(19) United States
(12) Patent Application Publication
(10) Pub. No.: US 2004/0123952 A1
(43) Pub. Date: Jul. 1, 2004

(54) FPD fabricating apparatus

(76) Inventors: Gwang Ho Hur, Yongin-shi (KR); Cheol Won Lee, Anyang-shi (KR); Jun Young Choi, Seoul (KR); Hyun Hwan Ahn, Seoul (KR)

Correspondence Address: MORGAN & FINNEGAN, L.L.P., 345 Park Avenue, New York, NY, 10154-0053, US

(21) Appl. No.: 10/729,471

(22) Filed: Dec. 5, 2003

(30) Foreign Application Priority Data
Dec. 5, 2002 (KR) 2002-76903
Dec. 5, 2002 (KR) 2002-76904
Dec. 9, 2002 (KR) 2002-77730
Feb. 28, 2003 (KR) 2003-12859
Mar. 21, 2003 (KR) 2003-17709
Oct. 15, 2003 (KR) 2003-71624

(51) Int. Cl. C23F 1/00; H01L 21/306

(52) U.S. Cl. 156/345.31

(57) ABSTRACT

An FPD fabricating apparatus according to the present invention comprises two chambers of a process chamber 130 and a transfer chamber 120. The substrate 140 is mounted on and transferred by one of two carrier plates 150a and 150b, each of which have a forked shape. The carrier plate lift pins 160b are raised up and fallen down while avoiding contact with the forked prongs of the robot arm 122a, so that the carrier plates 150a and 150b can be raised up and fallen down. The substrate lift pins 160a which are raised up and fallen down while avoiding contact with all the forked prongs of the robot arm 122a and the carrier plates 150a and 150b, so that only the substrate 140 mounted on the carrier plates 150a and 150b can be raised up and fallen down. According to the present invention, a load-lock chamber for transferring a substrate and a transfer chamber is incorporated into a single transfer chamber, so that space of the apparatus can be remarkably reduced and cost of the apparatus can be reduced. In addition, since the substrate is raised up and fallen down by using the carrier plates 150a and 150b, even large-area substrate can be stably transferred at high speed without bending, disrupting or vibration of the substrate.

### FIELD OF THE INVENTION

The present invention relates to a flat panel display (hereinafter, referred to as an FPD) fabricating apparatus, and more particularly, to an FPD fabricating apparatus capable of incorporating a load-lock chamber for transferring a substrate and a transfer chamber into a single transfer chamber and capable of transferring a large-area substrate with preventing the large-area substrate from bending.

### BACKGROUND OF THE INVENTION

In general, an FPD fabricating apparatus such as a dry Etcher, a chemical vapor deposition apparatus and a sputter comprises three vacuum chambers. The three vacuum chambers are a load-lock chamber, a process chamber, and a transfer chamber. The load-lock chamber is used for receiving a to-be-processed substrate from an exterior and ejecting a process-completed substrate to the exterior. The process chamber is used for performing a film deposition process, an etching process, or the like by using a plasma or an thermal energy. The transfer chamber is used for transferring the substrate from the load-lock chamber to the process chamber, or vice versa.

FIG. 1 is a plan view for explaining a conventional FPD fabricating apparatus.

Referring to FIG. 1, a robot 22 is provided in a transfer chamber 20. The robot 22 has a robot arm 22a for raising up and falling down a glass substrate 40. The robot arm raises up the substrate and transfers the substrate from a load lock chamber 10 to a process chamber 30, or vice versa.

In the process chamber 30, a series of processes are carried out under the state that the substrate 40 is mounted on the substrate support plate 36. In addition, the substrate 40 is raised up from the substrate support plate 36 or the substrate 40 is fallen down on the substrate support plate 36 by the aid of lift pins 32 or lift bars 34.

The lifting fins 32 are disposed at locations out of the substrate support 36 where the substrate 40 is mounted, but lift bars 34 are disposed at outside locations out of the substrate support plate where the substrate 40 is mounted. The upper end portions of the lift bars 34 are angled at a horizontal direction. When the angled end portions of the lift bars 34 are rotated toward the substrate 40, the lift bars 34 can support the substrate 40.

FIGS. 2a to 2f are cross-sectional views for explaining a series of operations of the conventional FPD fabricating apparatus shown in FIG. 1.

When a process is completed in the process chamber 130, the process-completed substrate 40b, which is mounted on the substrate support plate 36, stands by for a second. At that time, a door between the transfer chamber 20 and the process chamber 30 is opened, and then, the robot arm 22a on which a stand-by substrate 40a is mounted is entered into the process chamber 30. The substrate 40a is raised up by the lift bars 34 being raised up, and then, the robot arm 22a is left from the process chamber 30 and returned to the transfer chamber 20 (see FIGS. 2a and 2b).

When the robot arm 22a is returned to the transfer chamber 20, the process-completed substrate 40b which is mounted on the substrate support plate 36 is raised up by the lift pins 32 being raised up. After that, the robot arm 22a located in the transfer chamber 20 is entered into the process chamber 30 again. At that time, the lift pins 32 are fallen down, so that the substrate 40b can be mounted on the robot arm 22a. The robot arm 22a is returned to the transfer chamber 20 while bringing the process-completed substrate 40b back (see FIGS. 2c and 2d).

Next, the door between the transfer chamber 20 and the process chamber 30 is closed, and at the same time, the stand-by substrate 40a is mounted on the substrate support plate 36 by the lift pins 32 and the lift bars 34 being fallen down. After that, a series of processes are carried out (see FIG. 2e).

On the other hand, the robot arm 22a located in the transfer chamber 20 mounts the process-completed substrate 40b on a substrate storage site (not shown) in the load-lock chamber 10, puts the stand-by substrate 40c on its own hand, and rotates itself at 180 degree. In this state, the robot arm 22a stands by in the transfer chamber 20 until the processes in the process chamber 30 are completed (see FIG. 2f).

In the meantime, after a door between the load-lock chamber 10 and the transfer chamber 20 is closed, the process-completed substrate 40b is ejected from the load-lock chamber 10, and a newly to-to-processed substrate (not shown) is entered into the load-lock chamber 10. By doing so, the substrates are exchanged. At that time, the substrate is preferably exchanged while the processes are carried out in the process chamber 30. Therefore, it is necessary that the so-called venting and pumping of the load-lock chamber 10 are rapidly performed.

The conventional FPD fabricating apparatus described above utilizes two chambers of the load-lock chamber 10 and the transfer chamber 20 for transferring the substrate. Therefore, too large space of the apparatus is needed, so that the space can not be used effectively. In addition, special units such as vacuum pumps, valves, controller, or the like must be provided in order to maintain the two chambers, so that cost of the apparatus may be increased and production cost of FPDs may be increased.

Moreover, the size of the FPD substrate used for fabricating the FPDs has recently been increased up to about 2 m×2 m, which is twice as large as the conventional size. Furthermore, it is expected that the size of the substrate will be increased. Therefore, if the two chambers are used for this large-area substrate, there is a problem that too much volume of the clean room is needed.

As shown in FIG. 3a, in the aforementioned conventional FPD fabricating apparatus, the lift pins 32 are disposed within the distance of 15 mm from the circumferential portions of the substrate 40. In other words, the lift pins 32 are not disposed at the central portion of the substrate 40.

The reason that the lift pins 32 must be disposed not at the central portions but at the circumferential portion of the substrate is a temperature difference or a potential difference which is created between the locations A where the lift pins 32 are disposed and the other locations where the lift pins 32 are not disposed. Therefore, as shown in FIG. 3b, since etch rates are different among the location A and the other locations, specks 45 are disadvantageously generated on the surface of the substrate 40 after such an etching process.

However, the size of the substrate has recently been increased up to about 2 m×2 m. In a case that the large-area substrate 40 is raised up and transferred by supporting at only its circumferential portions like the conventional method, there occurs severe bending at the central portion of the substrate 40, so that the substrate 40 may be broken. In addition, there is a severe problem that the transfer of the substrate may be impossible because the robot arm can not be inserted below the substrate 40.

### SUMMARY OF INVENTION

In order to solve the above mentioned problems, an object of the present invention is to provide an FPD fabricating apparatus capable of incorporating a load-lock chamber for transferring a substrate and a transfer chamber into a single transfer chamber and capable of preventing bending of the substrate during the transferring.

In order to achieve the object, one aspect of the present invention is an FPD fabricating apparatus comprising: a process chamber in which a process is performed; a substrate support plate provided in the process chamber, wherein a to-be-processed substrate is mounted on the substrate support plate; a transfer chamber through which the substrate is entered into the process chamber from an exterior or through which the substrate is ejected from the process chamber to the exterior; a first carrier plate and a second carrier plate on which the substrate is mounted, wherein each of the first and second carrier plate has a forked shape of which ends are directed from the transfer chamber to the process chamber; a robot provided in the transfer chamber, wherein the robot comprises an arm of which end is directed from the transfer chamber to the process chamber, and wherein the arm has a reciprocating motion between the transfer chamber and the process chamber, thereby the robot transferring the first and second carrier plates; carrier plate lift pins provided in the transfer chamber and the process chamber, wherein the carrier plate lift pins are raised up and fallen down while avoiding contact with forked prongs of the robot arm, so that the first and second carrier plates mounted on the robot arm can be raised up and fallen down; and substrate lift pins provided in the transfer chamber and the process chamber, wherein the substrate lift pins are raised up and fallen down while avoiding forked prongs of the robot arm, the first carrier plate, and the second carrier plate, so that the substrates mounted on the carrier plates can be raised up and fallen down.

Another aspect of the present invention is an FPD fabricating apparatus comprising: a process chamber in which a process is performed; a substrate support plate provided in the process chamber, wherein a to-be-processed substrate is mounted on the substrate support plate; a transfer chamber through which the substrate is entered into the process chamber from an exterior or through which the substrate is ejected from the process chamber to the exterior; a robot provided in the transfer chamber, wherein the robot comprises a double blade member having an upper blade and a lower blade on which the substrate is mounted, wherein the double blade member has a reciprocating motion between the process chamber and the transfer chamber, and wherein each of the upper and lower blades has a forked shape of which end is directed from the transfer chamber to the process chamber; inner lift pins provided in the transfer chamber and the process chamber, wherein the outer lift pins are disposed below the substrate which is mounted on the double blade member, and wherein the inner lift pins are raised up and fallen down while avoiding contact with the forked prongs of the double blade; and outer lift pins provided in the transfer chamber and the process chamber, wherein the outer lift pins are disposed at outside locations just below the substrate which is mounted on the double blade member, wherein the end portions of the outer lift pins are angled at a horizontal direction, and wherein the outer lift pins are rotated on their own vertical shafts.

Still another aspect of the present invention is an FPD fabricating apparatus comprising: a process chamber in which a process is performed; a substrate support plate provided in the process chamber, wherein a to-be-processed substrate is mounted on the substrate support plate; a transfer chamber through which the substrate is entered into the process chamber from an exterior or through which the substrate is ejected from the process chamber to the exterior; a robot provided in the transfer chamber, wherein the robot comprises an arm, wherein the substrate is supported by the arm, and wherein the arm has a reciprocating motion between the process chamber and the transfer chamber; lower lift bars provided in the process chamber, wherein the lower lift pins are disposed at outside locations just below the substrate which is mounted on the arm, and wherein the end portions of the lower lift bars are angled at a horizontal direction; upper lift bars provided in the process chamber, wherein the upper lift pins are disposed at outside locations just below the substrate which is mounted on the arm, wherein the end portions of the upper lift bars are angled at a horizontal direction, and wherein the upper lift bars are arranged to be raised up to higher locations than the lower lift bars are; inner lift pins provided in the process chamber, wherein the inner lift pins are disposed below the substrate which is mounted on the arm, the inner lift pins are raised up and fallen down while avoiding contact with the arm; and stand-by lift bars provided in the transfer chamber, wherein the stand-by lift pins are disposed at outside locations just below the substrate which is mounted on the arm, and wherein the end portions of the stand-by lift bars are angled at a horizontal direction.

Further still another aspect of the present invention is an FPD fabricating apparatus comprising: a process chamber in which a process is performed; a transfer chamber being a passage through which the substrate is entered into the process chamber from an exterior or through which the substrate is ejected from the process chamber to the exterior; a transfer slider member provided in the transfer chamber, wherein a transfer slider member has a reciprocating translational motion between the process chamber and the transfer chamber to transfer a substrate; and a plurality of lift pins provided in the process chamber and the transfer chamber, wherein the substrate is raise up and fallen down by the plurality of lift pins.

Further still another aspect of the present invention is an FPD fabricating apparatus comprising: a process chamber in which a process is performed; a substrate support plate provided in the process chamber, wherein a substrate is mounted on the substrate support plate; a transfer chamber connected to the process chamber, wherein the transfer chamber is used as a passage through which the substrate is entered into the process chamber from an exterior and the substrate is ejected from the process chamber to the exterior; a robot provided in the transfer chamber, wherein the substrate is transferred by the robot, and wherein the robot has a reciprocating motion between the process chamber and the transfer chamber; a plurality of inner lift pins provided at locations out of the substrate support plate where the substrate is to be mounted, wherein the substrate is raised up and fallen down by the up-and-down motion of the inner lift pins; and fold-type outer lift bars provided at outside locations out of the substrate support plate where the substrate is to be mounted, wherein each of the fold-type outer lift bars comprises a vertical shaft and a horizontal support member, wherein the vertical shaft is arranged to have a up-and-down motion, wherein the horizontal support member comprises an outer support bar perpendicularly connected to the vertical shaft with a first joint which is provided at an upper end of the vertical shaft and an inner support bar connected to the outer support bar with a second joint which is provided at an end of the outer support bar, and wherein the horizontal support member is folded on the center of the second joint.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a plan view for explaining a conventional FPD fabricating apparatus;

FIGS. 2a to 2f are cross-sectional views for explaining a series of operations of the FPD fabricating apparatus of FIG. 1;

FIGS. 3a and 3b are views for explaining problems of the FPD fabricating apparatus of FIG. 1;

FIG. 4 is a plan view for explaining an FPD fabricating apparatus according to a first embodiment of the present invention;

FIGS. 5a to 5k are cross-sectional views for explaining a series of operations of the FPD fabricating apparatus according to the first embodiment of the present invention;

FIG. 6 is a plan view for explaining an FPD fabricating apparatus according to a second embodiment of the present invention;

FIGS. 7a to 7g are cross-sectional views for explaining a series of operations of the FPD fabricating apparatus according to the second embodiment of the present invention;

FIG. 8 is a plan view for explaining an FPD fabricating apparatus according to a third embodiment of the present invention;

FIGS. 9a to 9n are cross-sectional views for explaining a series of operations of the FPD fabricating apparatus according to the third embodiment of the present invention;

FIG. 10 is a plan view for explaining an FPD fabricating apparatus according to a fourth embodiment of the present invention;

FIG. 11 is a view for explaining a ball strew slider as an example of a transfer slider member in the FPD fabricating apparatus according to the fourth embodiment of the present invention;

FIG. 12 is a view for explaining a linear motor slider as another example of a transferring slider in the FPD fabricating apparatus according to the fourth embodiment of the present invention;

FIGS. 13a to 13n are cross-sectional views for explaining a series of operations of the FPD fabricating apparatus according to the fourth embodiment of the present invention;

FIG. 14a is a cross-sectional view for explaining a series of operations of a robot having a robot arm to which a joint member is provided in an FPD fabricating apparatus according to a fifth embodiment of the present invention;

FIG. 14b is a cross-sectional view for explaining a series of operations of a robot which is moving in a sliding manner in an FPD fabricating apparatus according to the fifth embodiment of the present invention;

FIG. 15a is a transverse cross-sectional view for explaining a construction of an outer lift bar and a robot finger in an FPD fabricating apparatus according to the fifth embodiment of the present invention;

FIG. 15b is a longitudinal cross-sectional view for explaining a construction and a position of an outer lift bar in an FPD fabricating apparatus according to the fifth embodiment of the present invention;

FIG. 15c is a enlarged view illustrating a part of FIG. 15b;

FIGS. 15d and 15e are views for explaining a construction and a series of operations of a fold-type outer lift bar having a belt structure in the FPD fabricating apparatus according to the fifth embodiment of the present invention; and

FIGS. 15f and 15g are views for explaining a construction and a series of operations of a joint-type outer lift bar having a joint structure in the FPD fabricating apparatus according to the fifth embodiment of the present invention;

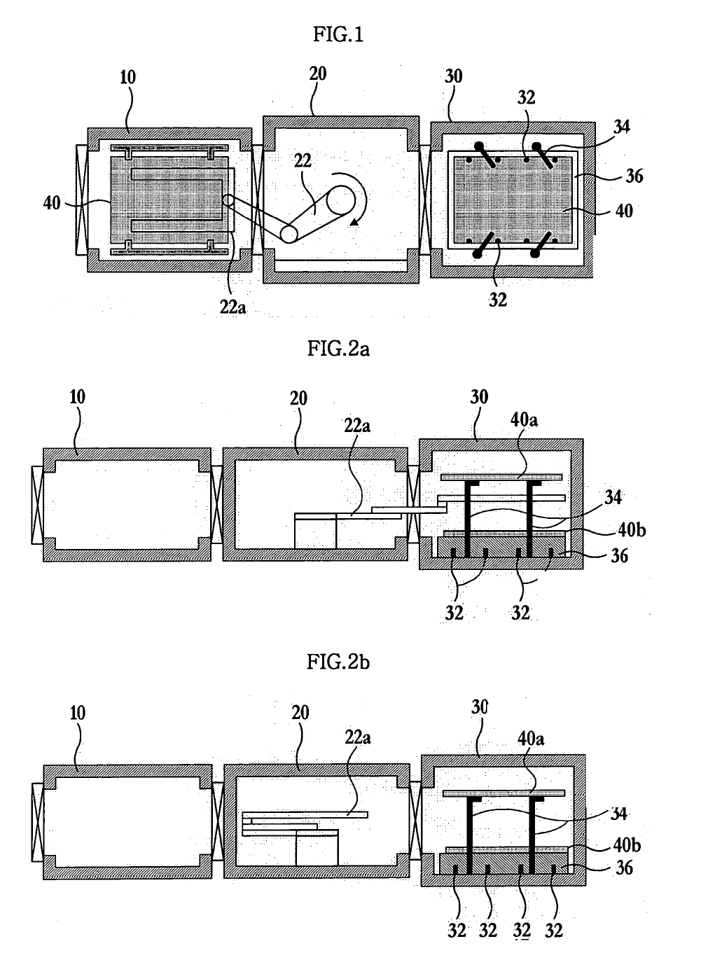

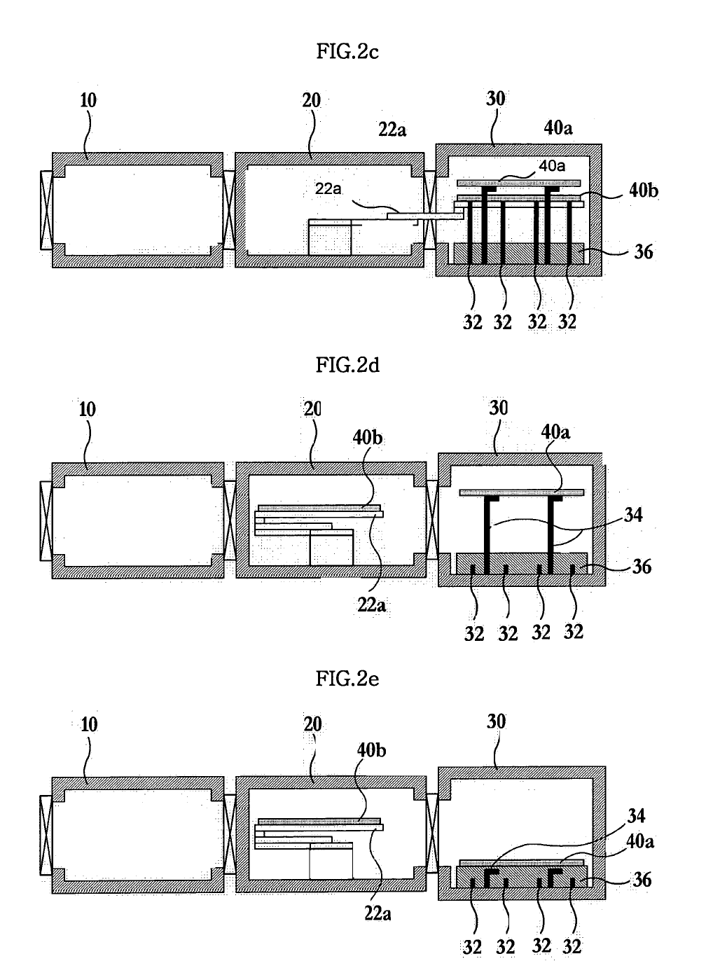

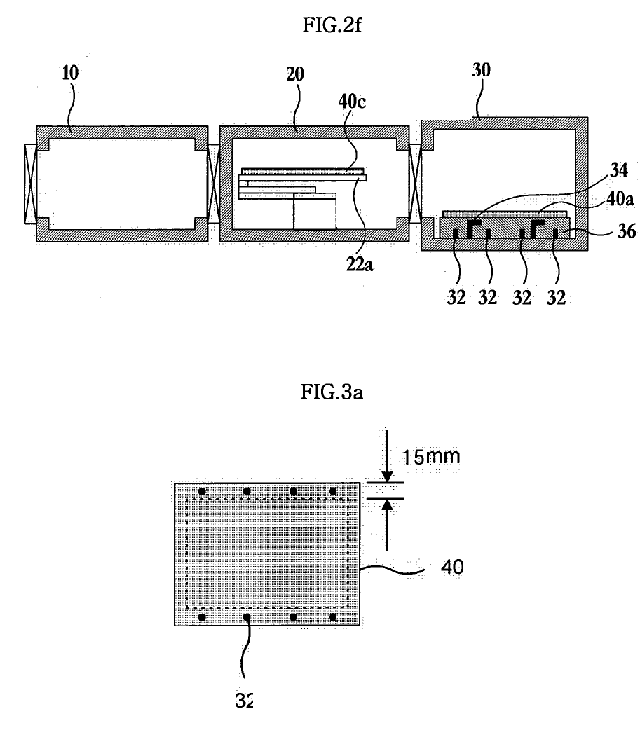

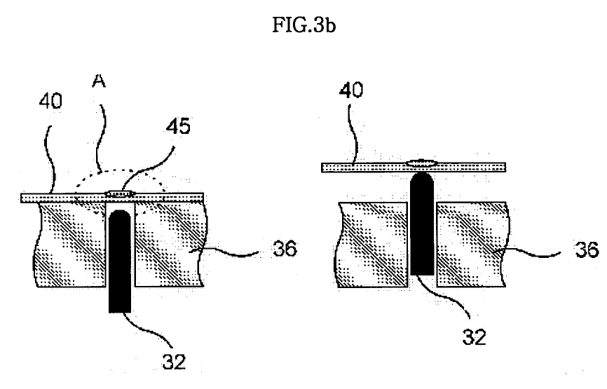

### DETAILED DESCRIPTION OF THE PREFERRED EMBODIMENTS

Now, the preferred embodiments according to the present invention will be described in detail with reference to the accompanying drawings.

[First Embodiment]

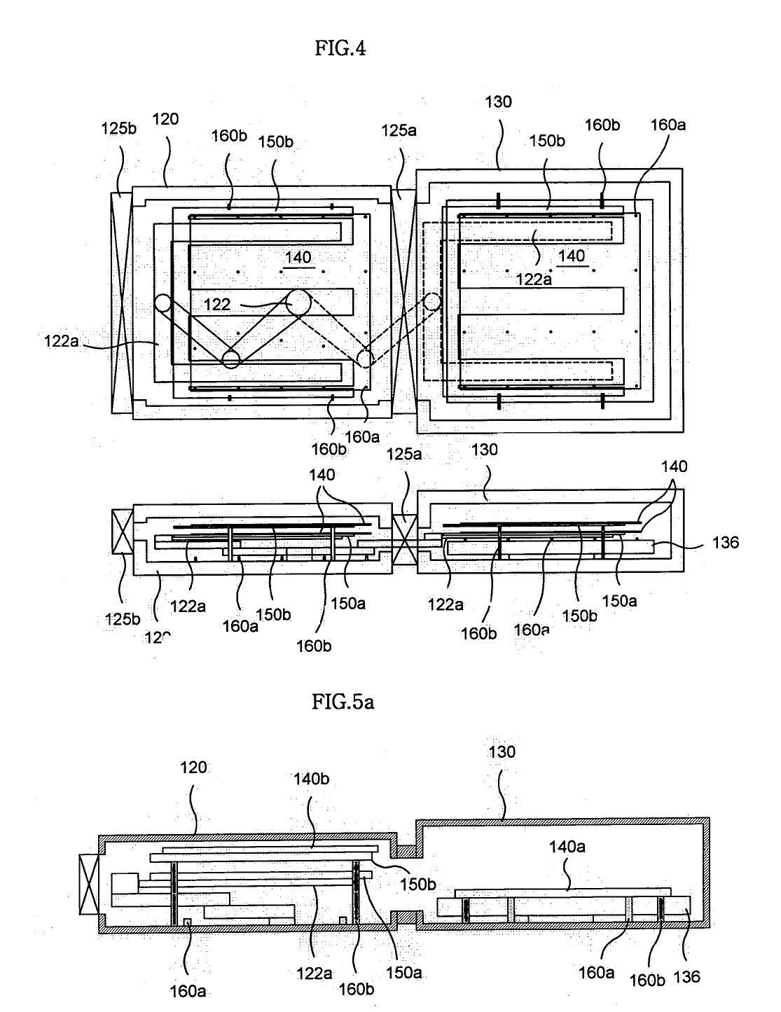

FIG. 4 is a plan view for explaining an FPD fabricating apparatus according to a first embodiment of the present invention.

Referring to FIG. 4, the FPD fabricating apparatus comprises two chambers, that is, a transfer chamber 120 and a process chamber 130 unlike the conventional FPD fabricating apparatus which comprises three chambers. In the transfer chamber 120, a single robot 122 for transferring a substrate and a vacuum pump (not shown) are provided.

A to-be-processed substrate is entered from the exterior via the transfer chamber 120 into the process chamber 130 by operation of the robot 122 and the gate valves 125a and 125b. A process-completed substrate is ejected from the process chamber 130 via the transfer chamber 120 to the exterior by operation of the robot 122 and the gate valves 125a and 125b.

In the process chamber 130, a substrate support plate 136 on which the to-be-processed substrate is mounted is provided. The substrate 140 is mounted on and transferred by two carrier plates 150a and 150b. The main purpose of the carrier plates 150a and 150b is to prevent the substrate from bending, so that the carrier plate is preferably made up of a material which is more inflexible and lighter than the substrate 140 and which is not chemically reactive.

Each of the carrier plates 150a and 150b and a robot arm has a forked shape of which ends are directed from the transfer chamber 120 to the process chamber 130. As such a shape, it is ensured that the carrier plates and the robot arm can avoid contact with substrate lift pins 160a or carrier plate lift pins 160b.

The carrier plates 150a and 150b are mounted on and transferred by the robot arm 122a. The robot arm 122a has a reciprocating translational motion between the process chamber 130 and the transfer chamber 120 without having rotational and up-and-down motions.

The carrier plate lift pins 160b provided in the transfer chamber 120 and the process chamber 130 are raised up and fallen down while avoiding contact with the forked prongs of the robot arm 122a, so that the carrier plates 150a and 150b mounted on the robot arm 122a can be raised up and fallen down.

The substrate lift pins 160a which are raised up and fallen down while avoiding contact with forked prongs of the robot arm 122a and the carrier plates 150a and 150b are provided in the transfer chamber 120 and the process chamber 130, so that only the substrate 140 mounted on the carrier plates 150a and 150b can be raised up and fallen down. It is preferable that the substrate lift pins 160a are disposed in order to uniformly support the entire substrate 140.

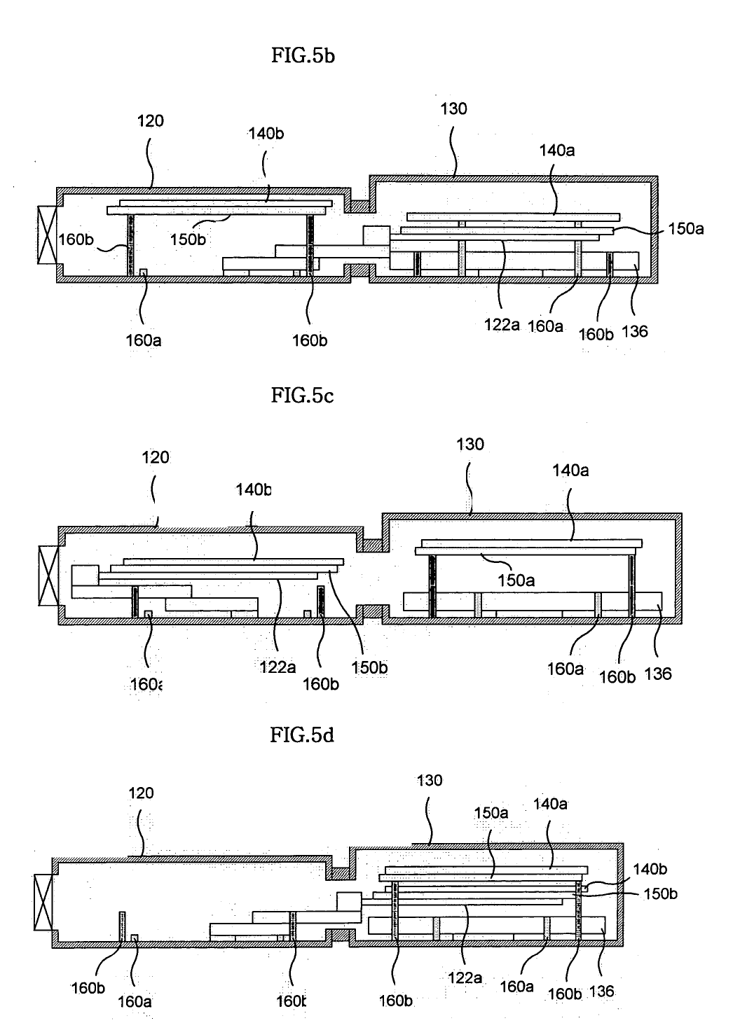

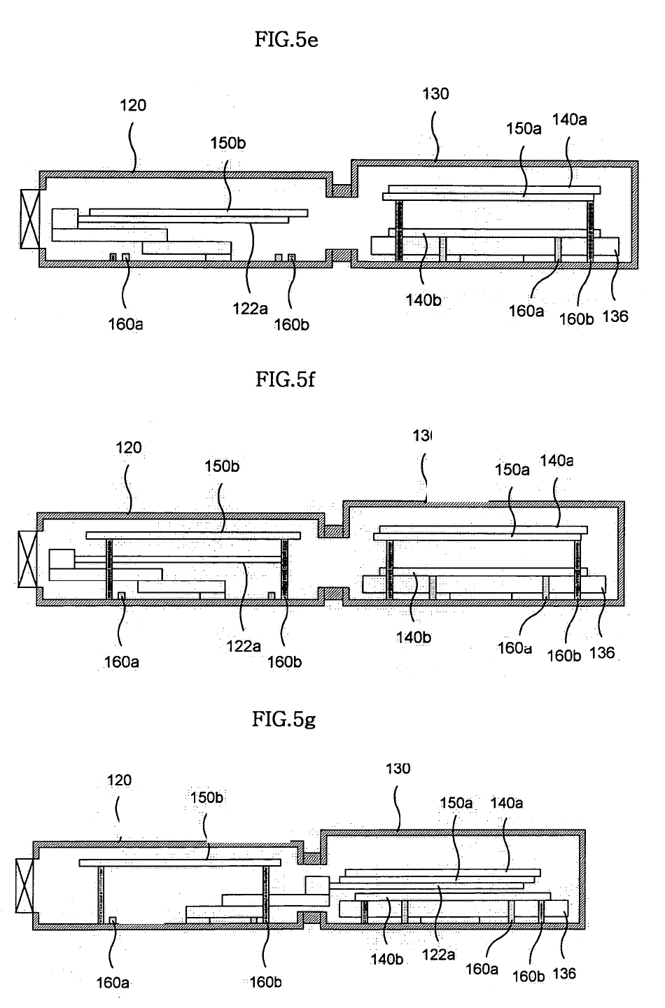

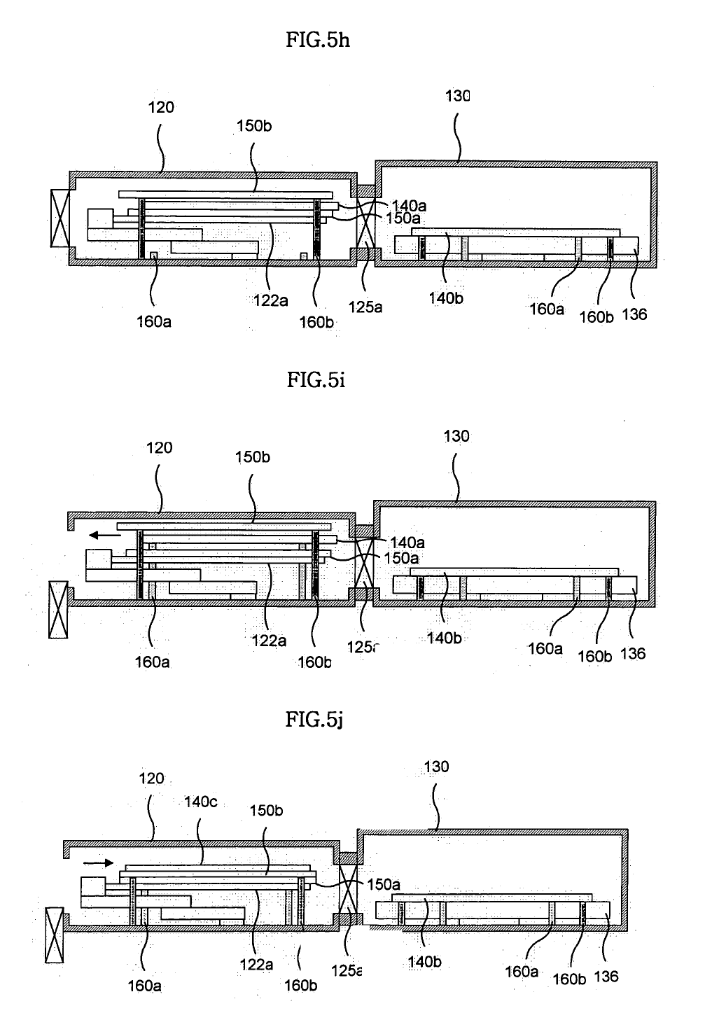

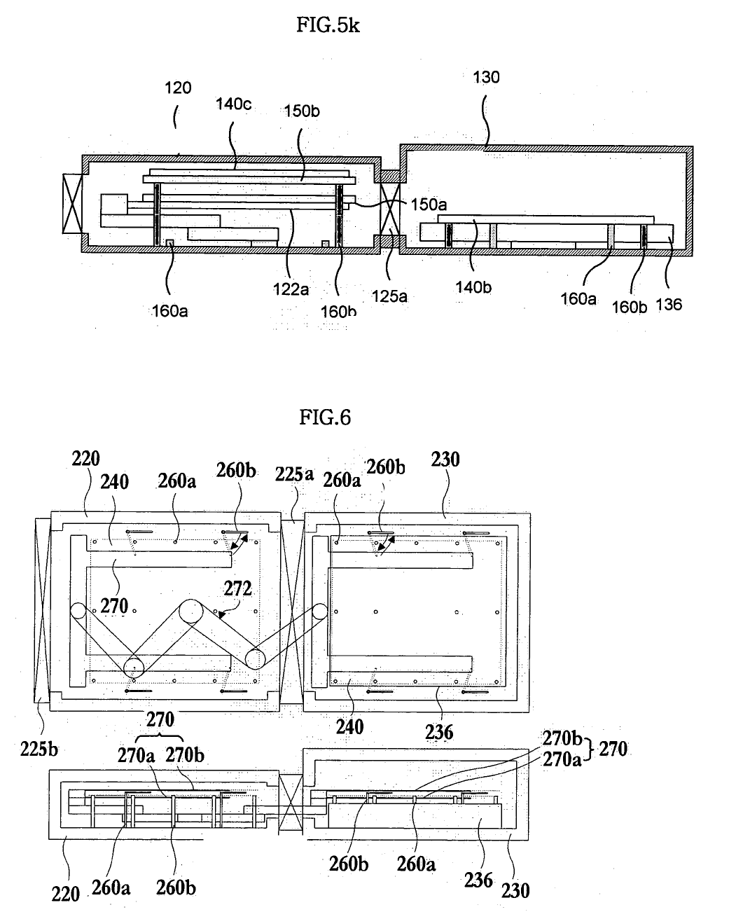

FIGS. 5a to 5k are cross-sectional views for explaining a series of operations of the FPD fabricating apparatus according to the first embodiment of the present invention.

As shown in FIG. 5a, in the process chamber 130, the process-completed substrate 140a is located on the substrate support plate 136. In the transfer chamber 120, no substrate is mounted on the first carrier plate 150a. Under the state, the first carrier plate 150a is mounted on the robot arm 122a while waiting for a process. The second carrier plate 150b on which the to-be-processed substrate 140b is mounted is raised up to an upper space above the robot arm 122a by the carrier-plate lift pin 160b in the transfer chamber 120.

As shown in FIG. 5b, the process-completed substrate 140a is raised up into the upper space above the substrate support plate 136 by the substrate lift pins 160a in the process chamber 130. The robot arm 122a, on which the first carrier plate 150a is mounted, is entered into the process chamber 130.

Next, as shown in FIG. 5c, the first carrier plate 150a and the process-completed substrate 140a are further raised up by the carrier-plate lift pins 16b in the process chamber 130 in order to prepare for exchange of substrates. The robot arm 122a, on which no one is mounted, is returned to the transfer chamber 120. And then, in the transfer chamber 120, the carrier-plate lift pins 160b is fallen down in order to mount the second carrier plate 150b on the robot arm 122a. Next, as shown in FIG. 5d, the robot arm 122a, on which the second carrier plate 150b is mounted, is entered into the process chamber 130.

Next, as shown in FIG. 5e, the to-be-processed substrate 140b, which is mounted on the second carrier plate 150b, is raised up by the substrate lift pins 160a in the process chamber 130. The robot arm 122a, on which the second carrier-plate 150b is mounted, is returned to the transfer chamber 120. And then, in the process chamber 130, the substrate lift pins 160a is fallen down in order to mount the to-be-processed substrate 140b on the substrate support plate 136 which is mounted on. Next, the second carrier plate 150b which is mounted on the robot arm 122a is raised up by the carrier-plate lift pins 160b in the transfer chamber 120, as shown in FIG. 5f.

Subsequently, as shown in FIG. 5g, the robot arm 122a on which no one is mounted is entered into the process chamber 130. And then, in the process chamber, the carrier-plate lift pins 160b is fallen down in order to mount the first carrier plate 150a on the robot arm 122a.

Next, as shown in FIG. 5h, the robot arm 122a on which the first carrier plate 150a is mounted is returned to the transfer chamber 120. And then, the gate valve 125a between the transfer chamber and the process chamber is closed and a predetermined process is independently performed. During the process, in the process chamber, all of the substrate lift pins 160a and the carrier-plate lift pins 160b are fallen down on the bottom in order to be protected by a cover (not shown) against a plasma, etc.

Next, while the transfer chamber 120 is vented, the process-completed substrate 140a is raised up from the first carrier plate 150a by the substrate lift pins 150a in the transfer chamber 120, as shown in FIG. 5i. At the time that the pressure of the transfer chamber 120 reaches the atmospheric pressure, the gate valve 125b between the transfer chamber and the exterior is opened and the process-completed substrate 140a is ejected from the transfer chamber to the exterior.

As shown in FIG. 5j, in the transfer chamber 120, the carrier-plate pins 160b are fallen down. Next, a newly-to-be-processed substrate is entered into the transfer chamber and mounted on the second carrier plate 150b. The gate valve 125b of the transfer chamber is closed, and then, the transfer chamber 120 is pumped down to vacuum. Finally, the carrier-plate lift pins 160b are raised up, so that the apparatus can be returned to the state of FIG. 5a. Under the state, the completion of the process in the process chamber 130 is waited for, as shown in FIG. 5k.

[Second Embodiment]

FIG. 6 is a plan view for explaining an FPD fabricating apparatus according to a second embodiment of the present invention.

Referring to FIG. 6, the FPD fabricating apparatus comprises two chambers, that is, a transfer chamber 220 and a process chamber 230 unlike the conventional FPD fabricating apparatus which comprises three chambers. In the transfer chamber 220, a single robot 272 for transferring a substrate and a vacuum pump (not shown) are provided.

A to-be-processed substrate is entered from the exterior via the transfer chamber 220 into the process chamber 230 by operation of the robot 222 and the gate valves 225a and 225b. A process-completed substrate is ejected from the process chamber 230 via the transfer chamber 220 to the exterior by operation of the robot 222 and the gate valves 225a and 225b. In the process chamber 230, a substrate support plate 236 on which the to-be-processed substrate is mounted is provided.

The robot 272 comprises a double blade member 270 having an upper blade 270b and a lower blade 270a. The substrate 240 is mounted on the upper blade 270b or the lower blade 270a.

The double blade member 270 has a reciprocating translational motion between the process chamber 230 and the transfer chamber 220 without having rotational and up-and-down motions. Each of the upper and lower blades 270b and 270a has a forked shape of which end is directed from the transfer chamber 220 to the process chamber 230. As such a shape, it is ensured that the blades can avoid contact with inner lift pins 260a or outer lift pins 260b.

The inner lift pins 260a, which are provided below the substrate 240 in the transfer chamber 220 and the process chamber 230, are raised up and fallen down while avoiding contact with the forked prongs of the double blade member 270. It is preferable that the substrate lift pins 260a are disposed to uniformly support the entire substrate 240, so that the bending of the substrate 240 can be prevented.

The outer lift pins 260b provided in the transfer chamber 220 and the process chamber 230 are disposed at outside locations just below the substrate 240 which is mounted on the double blade member 270. The end portions of the outer lift pins 260b are angled at a horizontal direction. In addition, the outer lift pins 260b can be rotated on their own vertical shafts. After the outer lift pins 260b are rotated to insert their angled end portions below the substrate 240, the substrate 240 can be raised up or fell down by the outer lift pins 260b.

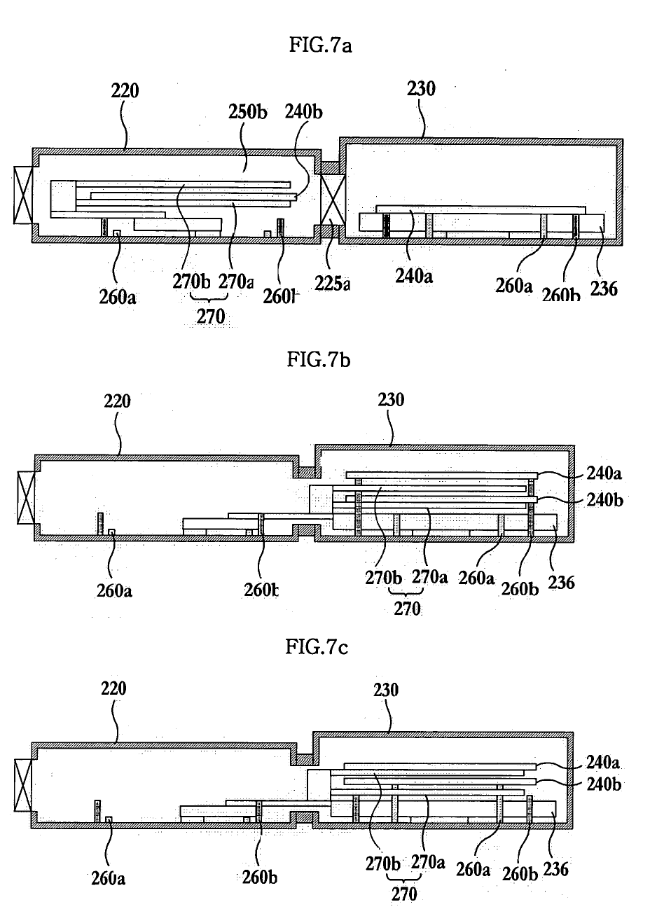

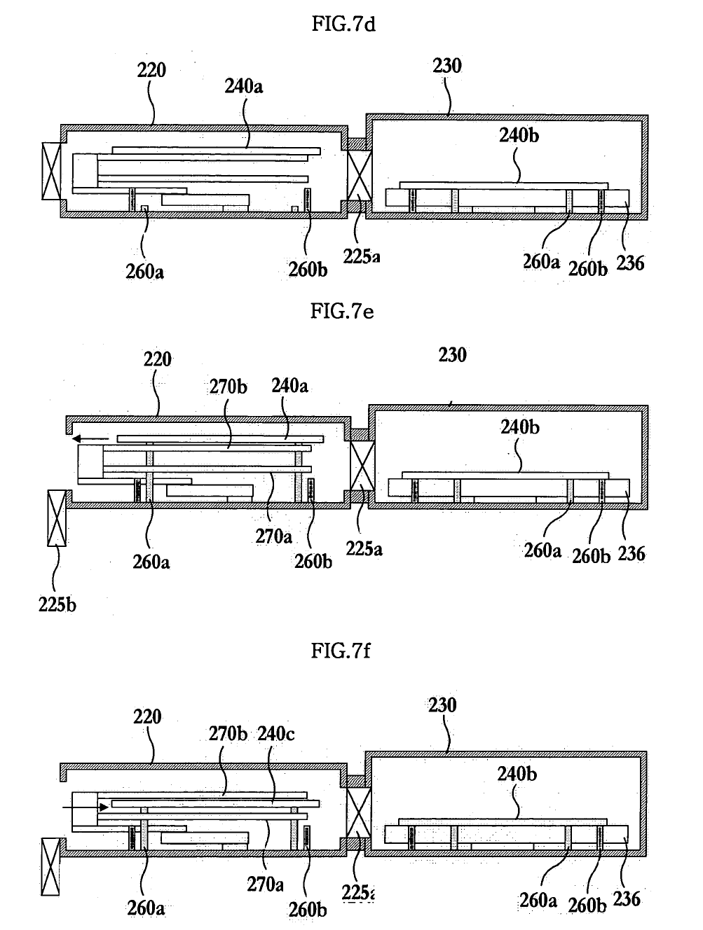

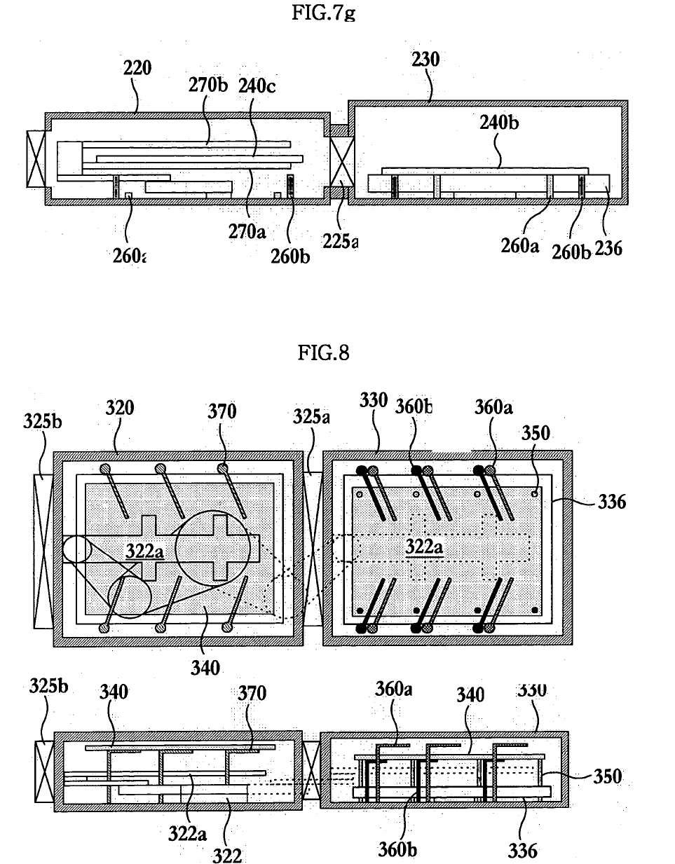

FIGS. 7a to 7g are cross-sectional views for explaining a series of operations of the FPD fabricating apparatus according to the second embodiment of the present invention.

As shown in FIG. 7a, in the process chamber 230, the process-completed substrate 240a is mounted on the substrate support plate 236. No substrate is mounted on the upper blade 270b and the to-be-processed substrate 240b is mounted on only the lower blade 270a. Under the state, the double blade member of the transfer chamber 220 waits for a process.

As shown in FIG. 7b, in the process chamber 230, the process-completed substrate 240a is raised up from the substrate support plate 236 by the inner lift pins 260a. Next, in the process chamber 230, the outer lift pins 260b are rotated and inserted below the process-completed substrate 240a to further raise up the process-completed substrate 240a. Next, in the process chamber 230, the inner lift pins 260a are fallen down to their initial levels. The double blade member is entered into the process chamber 230.

Next, as shown in FIG. 7c, in the process chamber 230, the to-be-processed substrate 240b is raised up from the lower blade 270a by the inner lift pins 260a being raised up. The process-completed substrate 240a is mounted on the upper blade 270b by the outer lift pins 260b being fallen down and rotated.

Next, as shown in FIG. 7d, the double blade member 270 is returned to the transfer chamber 220. In the process chamber 230, the to-be-processed substrate 240b is mounted on the substrate support plate 236 by the inner lift pins 260a being fallen down. And then, the gate valve 225a between the transfer chamber and the process chamber is closed and a predetermined process is independently performed. During the process, in the process chamber, all of the inner lift pins 260a and the outer lift pins 260b are fallen down on the bottom in order to be protected by a cover (not shown) against a plasma, etc.

Next, while the transfer chamber 220 is vented, the process-completed substrate 240a is raised up from the upper blade 270b by the inner lift pins 260a being raised, as shown in FIG. 7e. At the time that the pressure of the transfer chamber 220 reaches the atmospheric pressure, the gate valve 225b between the transfer chamber and the exterior is opened and the process-completed substrate 240a is ejected from the transfer chamber to the exterior by an external robot (not shown).

Next, a newly-to-be-processed substrate 240c is entered into the transfer chamber 220 and supported by the inner lift pins 260a, as shown in FIG. 7f. The to-be-processed substrate 240c is mount on the lower blade 270a by the inner lift pins 260a being fallen down, so that the apparatus can be in the state of FIG. 7a. Under the state, the completion of the process in the process chamber 230 is waited for, as shown in FIG. 7g.

As described above, according to the second embodiment, the two blades of the double blade member 270 can be simultaneously operated by the single robot arm. Therefore, by one operation, the process-completed substrate 240a is ejected from the process chamber 230, and at the same time, the to-be-processed substrate 240b is entered into the process chamber 230. Unlike the prior art, the repetition of two operations is not necessary, so that the transfer time can be reduced.

[Third Embodiment]

FIG. 8 is a plan view for explaining an FPD fabricating apparatus according to a third embodiment of the present invention.

Referring to FIG. 8, the FPD fabricating apparatus comprises two chambers, that is, a transfer chamber 320 and a process chamber 330 unlike the conventional FPD fabricating apparatus which comprises three chambers. In the transfer chamber 320, a single robot 322 for transferring a substrate and a vacuum pump (not shown) are provided.

A to-be-processed substrate is entered from the exterior via the transfer chamber 320 into the process chamber 330 by operation of the robot 322 and the gate valves 325a and 325b. A process-completed substrate is ejected from the process chamber 330 via the transfer chamber 320 to the exterior by operation of the robot 322 and the gate valves 325a and 325b.

In the process chamber 330, a substrate support plate 336 on which the to-be-processed substrate is mounted is provided. The substrate 340 is mounted on and transferred by a robot arm 322a. The robot arm 322a has a reciprocating translational motion between the process chamber 330 and the transfer chamber 320 without having rotational and up-and-down motions. The robot arm 322a is extended in a direction from the transfer chamber 320 to the process chamber 330 to support a central portion of the substrate 340.

Upper lift bars 360a, lower lift bars 360b, and stand-by lift bars 370 are disposed at outside locations just below the substrate 340. The end portions of the upper lift bars 360a, the lower lift bars 360b, and the stand-by lift bars 370 are angled at a horizontal direction. In addition, the upper lift bars 360a, the lower lift bars 360b, and the stand-by lift bars 370 can be rotated on their own vertical shafts. After the upper lift bars 360a, the lower lift bars 360b, and the stand-by lift bars 370 are rotated to insert their angled end portions below the substrate 340, the substrate 340 can be raised up or fell down by the upper lift bars 360a, the lower lift bars 360b, and the stand-by lift bars 370. The angled end portions of the upper lift bars 360a, the lower lift bars 360b, and the stand-by lift bars 370 are stretched to the central portion of the substrate 440.

The upper lift bars 360a and the lower lift bars 360b are provided in the process chamber 330, and the stand-by lift bars 370 are provided in the transfer chamber 320. The upper lift bars 360a are arranged to be raised up to higher locations than the lower lift bars 360b are.

The inner lift pins 350, which are provided below the substrate 340 in the process chamber 330, are raised up and fallen down while avoiding contact with the robot arm 322a. Since the robot arm 322a mainly supports the central portion of the substrate 340, the inner lift pins are arranged to support the circumferential portions of the substrate 340. If only the inner lift pins 350 are arranged to support the substrate 340, the substrate 340 may be bended. Therefore, the lift bars are added to support the central portion of the substrate 340.

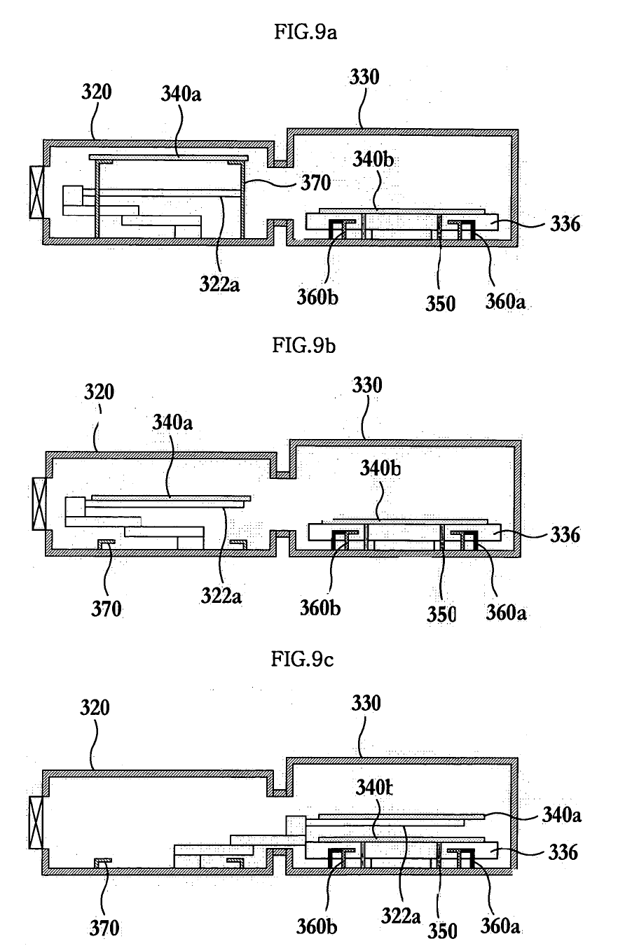

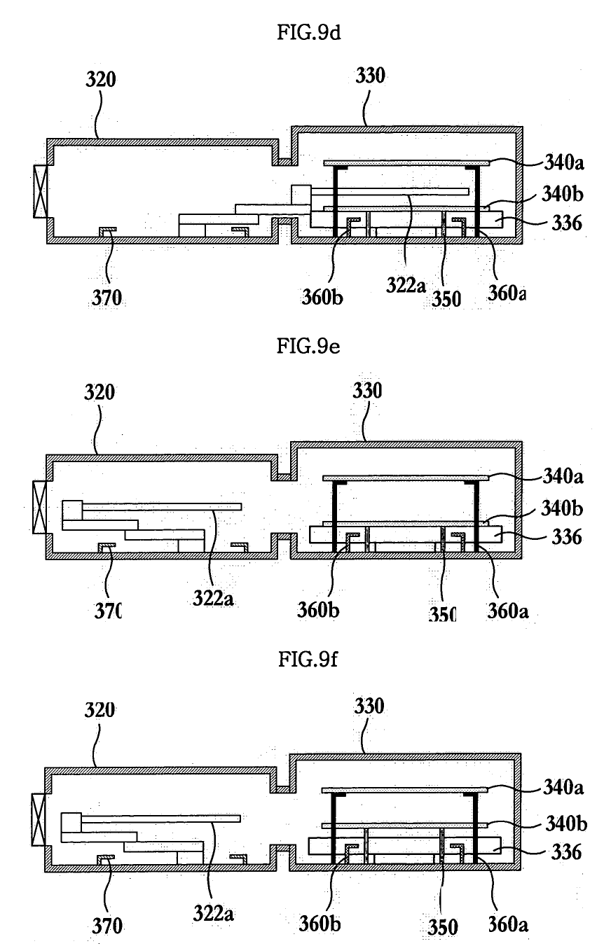

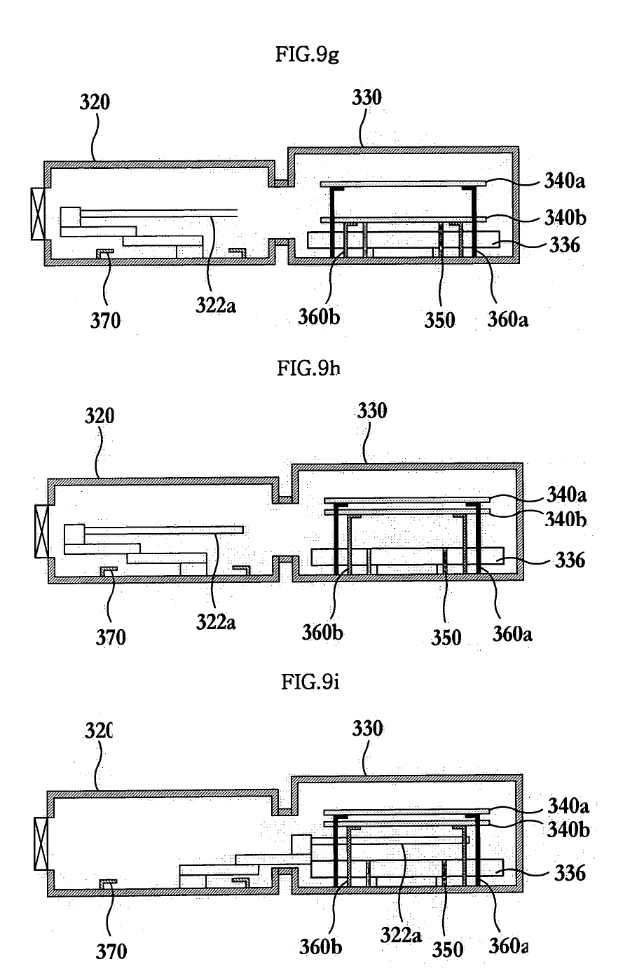

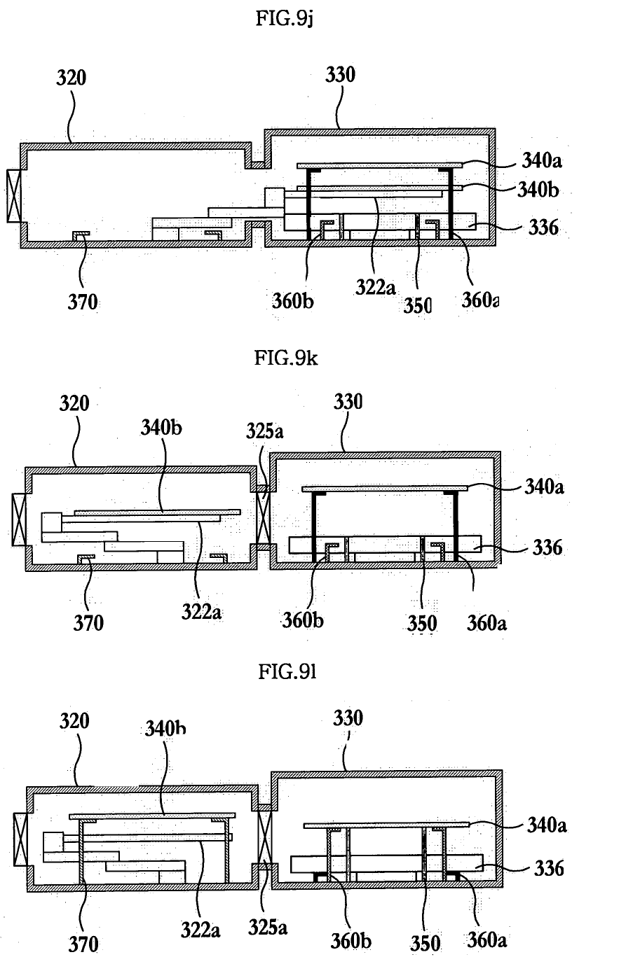

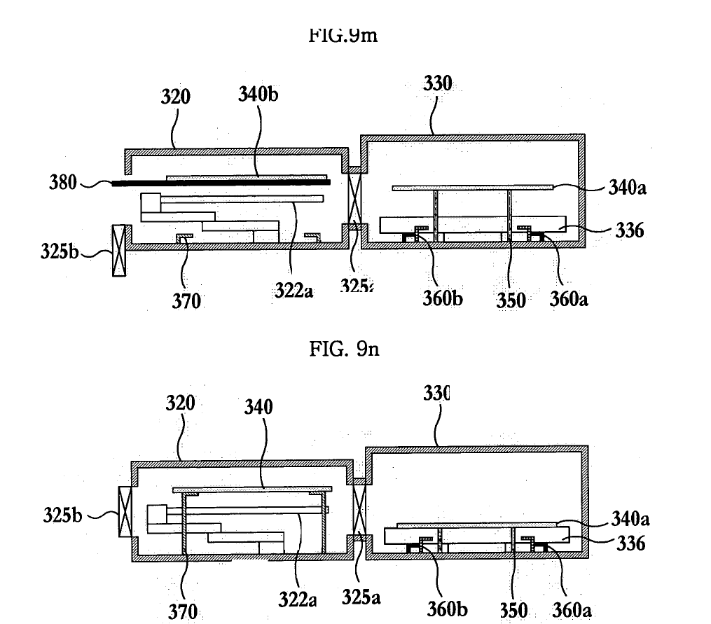

FIGS. 9a to 9n are cross-sectional views for explaining a series of operations of the FPD fabricating apparatus according to the third embodiment of the present invention.

As shown in FIG. 9a, in the process chamber 330, the process-completed substrate 340b is mounted on the substrate support plate 336. In the transfer chamber 320, the to-be-processed substrate 340a is raised up to a space above the robot arm 322a by the stand-by lift bars 370 being raised up. And then, as shown in FIG. 9b, the to-be-processed substrate 340a is mounted on the robot arm 322a by the stand-by lift bars 370 being fallen down.

After the robot arm 322a is entered into the process chamber 330, the to-be-processed substrate 340a is raised up from the robot arm 322a by the upper lift bars 360a being raised up, as shown in FIGS. 9c and 9d. Next, the robot arm 322a, on which no one is mounted, is returned to the transfer chamber 320, as shown in FIG. 9e.

When the process-completed substrate 340b is raised up to some height by the inner lift pins 350, the lower lift bars 360b are rotated to be inserted below the substrate 340b. The purpose of the lower lift bars is to further support the substrate 340b which may be bended due to its own weight. And then, the inner lift pins 350 are fallen down, as shown in FIGS. 9f and 9h.

Next, the robot arm 322a, on which no substrate is mounted, is entered into the process chamber 330. The robot arm 322a is located below the process-completed substrate 340b, as shown in FIG. 9i. The process-completed substrate 340b is mounted on the robot arm 322a by the lower lift bars 360b being fallen down. The robot arm 322a is returned to the transfer chamber 320. And then, the gate valve 325a between the transfer chamber and the process chamber is closed, as shown in FIGS. 9j and 9k.

Next, while the upper lift bars 360a are fallen down, the to-be-processed substrate 340a is transferred to the lower lift bars 360a and the inner lift pins 350 which are raised up. At this time, the to-be-processed substrate 340a is firstly transferred to the lower lift bars 360a. Next, the to-be-processed substrate 340 is transferred to the inner lift pins 350. Finally, the to-be-processed substrate 340 is mounted on the substrate 336.

Next, while the process-completed substrate 340b is raised up by the stand-by lift bars 370 being raised up, the transfer chamber 320 is vented in order to prepare for ejecting the process-completed substrate 340b to the exterior. At the time that the pressure of the transfer chamber 320 reaches the atmospheric pressure, the gate valve 325b between the transfer chamber and the exterior is opened and the process-completed substrate 340b is ejected from the transfer chamber by an external robot 380. Next, a newly-to-be-processed substrate 340c is entered into the transfer chamber 320 and supported by the stand-by lift bars 370. After the gate valve 325b is closed, the transfer chamber 320 is pumped down. During the pumping, the to-be-processed substrate 340c is mounted on the robot arm 322a by the stand-by lift bars 370 being fallen down. This state is maintained until the process in the process chamber is completed. The aforementioned operations are shown in FIGS. 9l and 9n. As a result, the apparatus is returned to the state of FIG. 9a, and a series of the process is repeatedly performed on the substrate.

After the substrate 340a is mounted on the substrate support plate 336, the process starts to be performed. During the process, in the process chamber, all of the inner lift pins 350 and the lift bars 360a and 360b are fallen down below the substrate support plate 336 in order to be protected by a cover (not shown) against a plasma, etc.

[Fourth Embodiment]

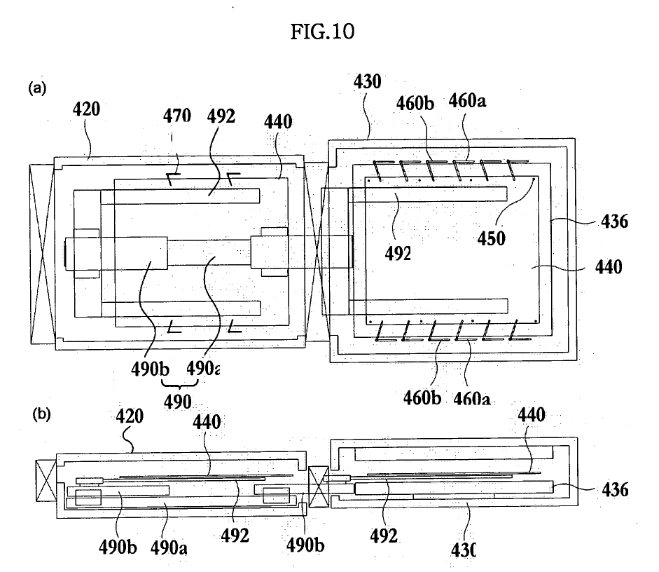

FIG. 10 is a plan view for explaining an FPD fabricating apparatus according to a fourth embodiment of the present invention.

Referring to FIG. 10, the FPD fabricating apparatus comprises two chambers, that is, a transfer chamber 420 and a process chamber 430 unlike the conventional FPD fabricating apparatus which comprises three chambers. In other words, unlike the conventional FPD fabricating apparatus, only the transfer chamber 420 functions as a passage through which the substrate is entered into the process chamber 430 from an exterior and through which the substrate is ejected from the process chamber 430 to the exterior. In the transfer chamber 420, a transfer slider member 490 having a reciprocating translational motion between the process chamber 430 and the transfer chamber 420 to transfer a substrate and a vacuum pump (not shown) are provided.

Preferably, the transfer slider member 490 is a two-stage slider member comprising a pair of a lower slider 490a and an upper slider 490b in order to use the small space effectively. If the transfer slider member 490 comprises a single transfer slider, the transfer chamber must be elongated to accommodate the length of the forked blade 492, so that space can not be used effectively and it may take a long time to pump and vent the chamber.

In the process chamber 430, a substrate support plate 436 on which the to-be-processed substrate is mounted is provided. The substrate 440 is mounted on and transferred by a blade 492. The blade 492 has a reciprocating translational motion along the transfer slider member without having rotational and up-and-down motions.

First outer lift bars 460a, second outer lift pins 460b, and stand-by outer lift pins 470 are disposed at outside locations below the substrate 440. The end portions of the first outer lift pins 460a, the second outer lift pins 460b, and the stand-by outer lift pins 470 are angled at a horizontal direction. In addition, the first outer lift bars 460a, the second outer lift pins 460b, and the stand-by outer lift pins 470 can be rotated on their own vertical shafts. When the first outer lift pins 460a, the second outer lift pins 460b, and the stand-by outer lift pins 470 are rotated to insert their angled end portions below the substrate 440, substrate 440 is raised up or fell down by the first outer lift pins 460a, the second outer lift pins 460b, and the stand-by outer lift pins 470.

The first outer lift bars 460a and the second outer lift pins 460b are provided in the process chamber 430, and the stand-by outer lift pins 470 are provided in the transfer chamber 420. The first outer lift bars 460a are arranged to be raised up to higher locations than the second outer lift pins 460b are. Inner lift pins 450 are provided below the substrate 440 are raised up and fallen down while avoiding contact with the blade 492.

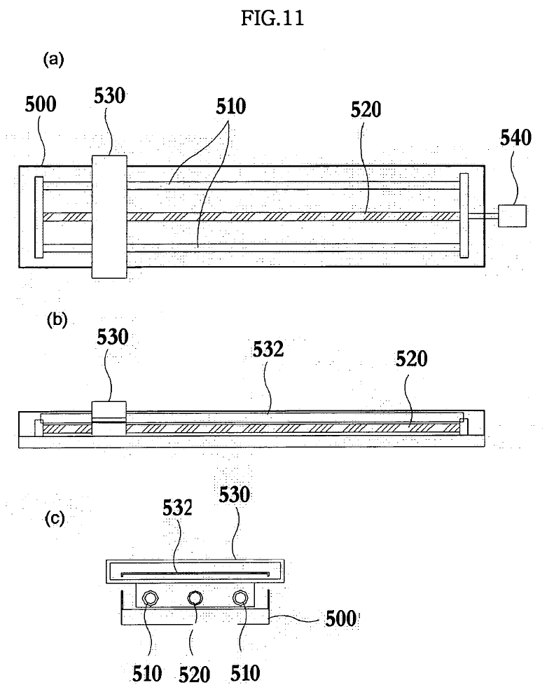

FIG. 11 is a view for explaining a ball strew slider as an example of a transfer slider member, wherein (a) is a plan view, (b) is a front view, and (c) is a side view.

The transfer slider member 490 is constructed in a two-stage structure comprising the lower slider 490a and the upper slider 490b. Each of the lower slider 490a and the upper slider 490b comprises: a reference panel 500; liner guides 510 provided on the reference panel 500; a carrier 530 having a reciprocating translational motion along the liner guides 510; a ball screw 520 provided in parallel to the liner guides 510 for allowing the carrier 530 to have the reciprocating translational motion; and a drive motor 540 for driving a rotation of the ball screw 520.

The reference panel 500 of the upper slider 490b is mounted on the carrier 530 of the lower slider 490a, and the blade 492 for supporting the substrate is mounted on the carrier 530 of the upper slider 490b.

A screw hole is provided below the carrier 530 to be engaged with the ball screw 520. By the rotation of the ball screw 520, the carrier 530 which is stably inserted into the carrier slot 532 is moved in a translational manner along the liner guides 510. Preferably, for the purpose of the smooth motion of the carrier, vacuum grease is applied to the ball screw 520 and the liner guides 510. The vacuum grease is a kind of grease which generates little dust in vacuum.

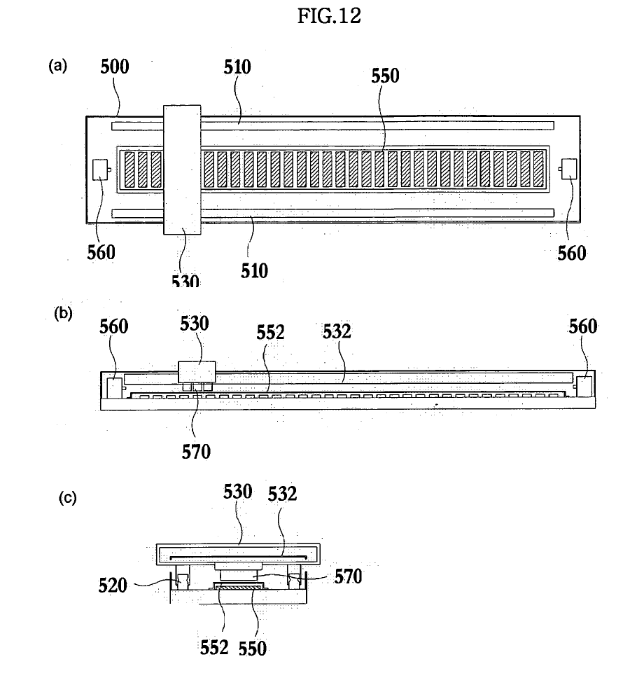

FIG. 12 is a view for explaining a linear motor slider as another example of a transfer slider member, wherein (a) is a plan view, (b) is a front view, and (c) is a side view.

The transfer slider member 490 is also constructed in a two-stage structure comprising the lower slider 490a and the upper slider 490b. Each of the lower slider 490a and the upper slider 490b comprises: a reference panel 500; liner guides 510 provided on the reference panel 500; a carrier 530 having a reciprocating translational motion along the liner guides 510; a iron-core coil 570 provided below the carrier 530; and a permanent magnet 550 provided opposite to iron-core coil 570 and in parallel to the liner guides 510. The carrier has the reciprocating translational motion between stoppers 560 by the interaction between the iron-core coil 570 and the permanent magnet 550 according to the same operational principle as a general motor.

The reference panel 500 of the upper slider 490b is mounted on the carrier 530 of the lower slider 490a, and the blade 492 for supporting the substrate is mounted on the carrier 530 of the upper slider 490b.

It is preferable that the permanent magnet 550 is covered with a thin plate 552 made up of stainless steel or aluminum and the iron-core coil is molded with epoxy or the like in order to prevent the magnet or the coil from being contaminated due to chemicals from the process chamber 430. In particular, it is preferable that the thin plate 552 for covering the magnet is sealed with an O-ring or the like in order to prevent dust and contaminants generated from the magnet or the like from leaking out. It is preferable that a cable specially manufactured for a clean room is used for the cable (not shown) for supplying power to the linear motor including the iron-core coil 570 and the permanent magnet 550, since a general cable may generate dust from its repeated friction and bending during the motion of the carrier 530.

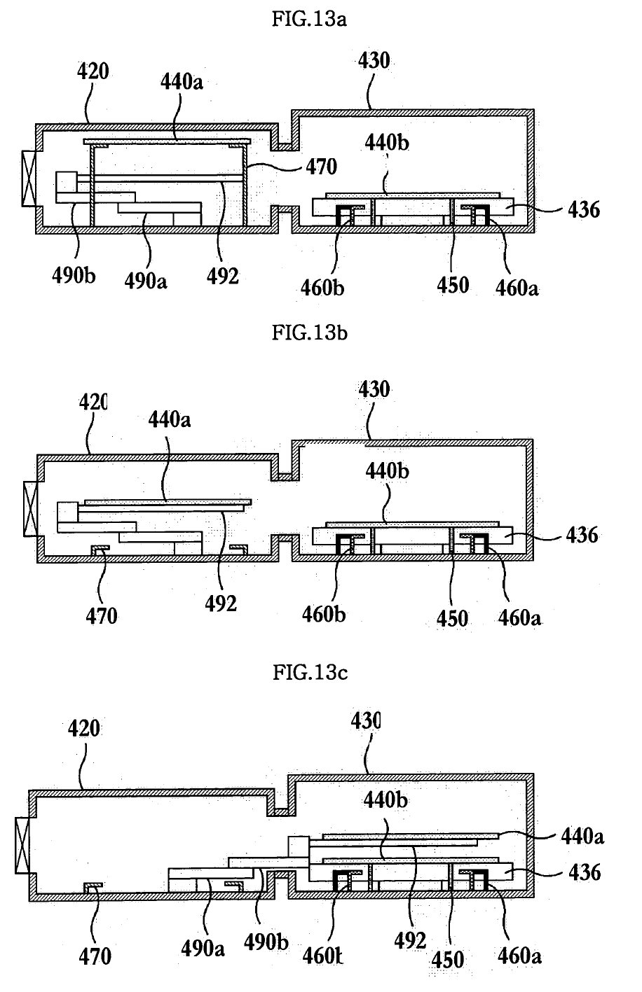

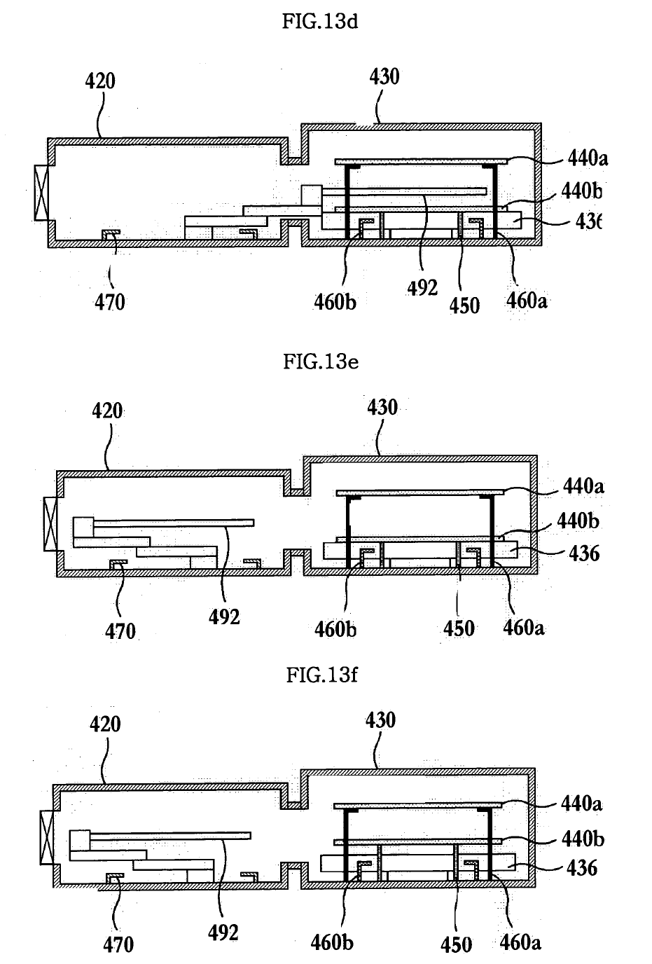

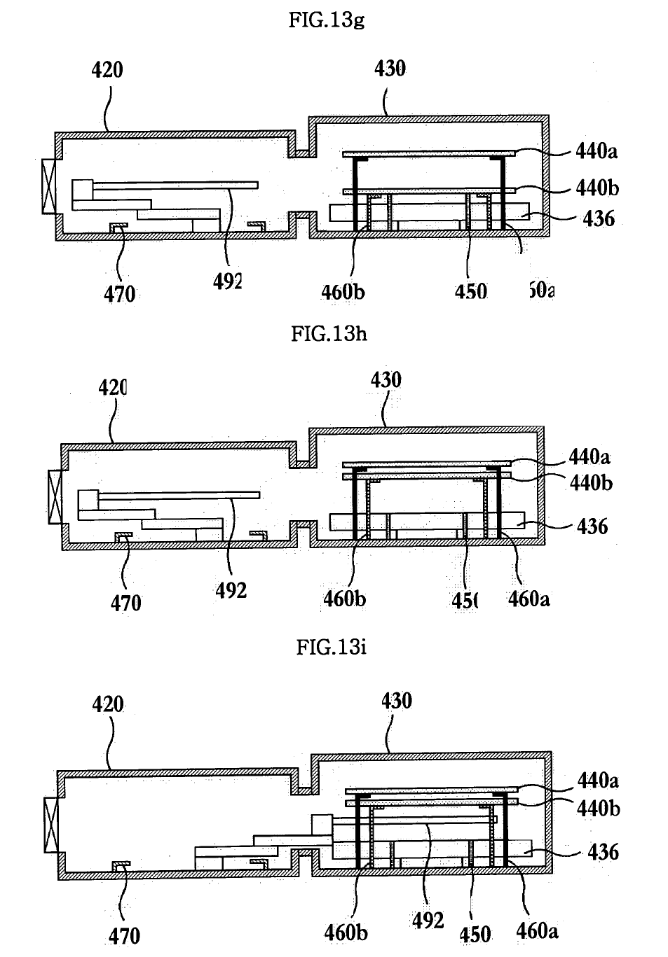

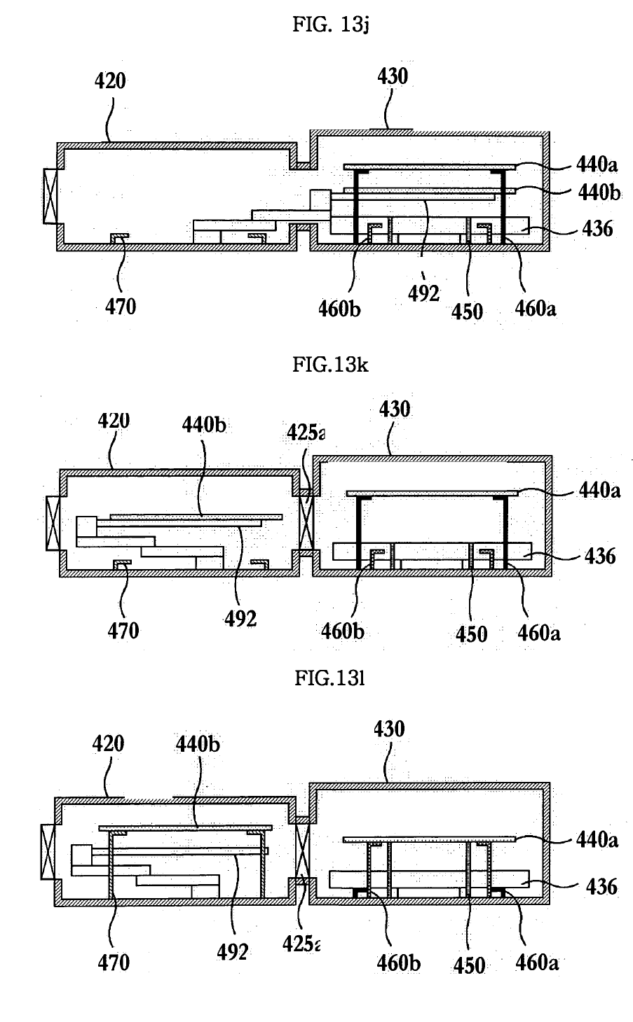

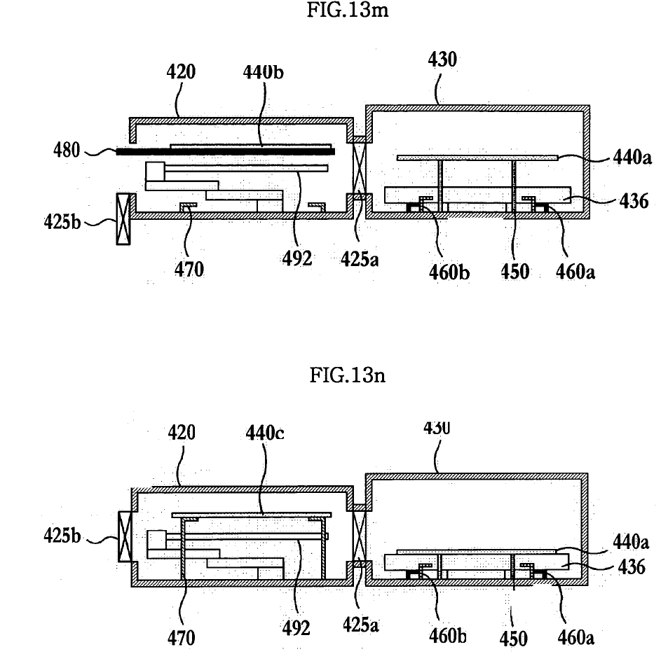

FIGS. 13a to 13n are cross-sectional views for explaining a series of operations of the FPD fabricating apparatus according to the fourth embodiment of the present invention.

As shown in FIG. 13a, in the process chamber 430, the process-completed substrate 440b is mounted on the substrate support plate 436. In the transfer chamber 420, the blade 492 is provided and the to-be-processed substrate 440a is raised up to a space above the blade 492 by the stand-by outer lift pins 470 being raised up. And then, the to-be-processed substrate 440a is mounted on the blade 492 by the stand-by outer lift pins 470 being fallen down, as shown in 13b. At this time, the blade 492 needs not to be moved up and down.

Next, after the blade 492 is entered into the process chamber 430, the to-be-processed substrate 440a is raised up from the blade 492 by the first outer lift pins 460a, as shown in FIGS. 13c and 13d. And then, the blade 492 on which no one is mounted is returned to the transfer chamber 420, as shown in FIG. 13e.

When the process-completed substrate 440b is raised up to some height by the inner lift pins 450, the second outer lift pins 460b are rotated to be inserted below the substrate 440b. The purpose of the second outer lift bars is to further support the substrate 440b which may be bended due to its own weight. And then, the inner lift pins 450 are fallen down, as shown in FIGS. 13f and 13h.

Next, the blade 492 on which no one is mounted is entered into the process chamber 430. The blade 492 is located below the process-completed substrate 440b, as shown in FIG. 13i. The process-completed substrate 440b is mounted on the blade 492 by the second outer lift pins 460b being fallen down. The blade 492 is returned to the transfer chamber 420. And then, the gate valve 425a between the transfer chamber and the process chamber is closed, as shown in FIGS. 13j and 13k.

Next, while the first outer lift pins 460a are fallen down, the to-be-processed substrate 440a is transferred to the second outer lift pins 460b and inner lift pins 450 being raised up. At this time, the to-be-processed substrate 440a is firstly transferred to the second outer lift pins 460b. Next, to-be-processed substrate 440 is transferred to the inner lift pins 450. Finally, the to-be-processed substrate 440 is mounted on the substrate 436.

Next, while the process-completed substrate 440b is raised up by the stand-by outer lift pins 470 being raised up, the transfer chamber 420 is vented in order to prepare for ejecting the process-completed substrate 440b to the exterior. At the time that the pressure of the transfer chamber 420 reaches the atmospheric pressure, the gate valve 425b between the transfer chamber and the exterior is opened and the process-completed substrate 440b is ejected from the transfer chamber by an external robot 480. Next, a newly-to-be-processed substrate 440c is entered into the transfer chamber 420 and supported by the stand-by outer lift pins 470. After the gate valve 425b is closed, the transfer chamber 420 is pumped down. During the pumping, the to-be-processed substrate 440c is mounted on the blade 492 by the stand-by outer lift pins 470 being fallen down. This state is maintained until the process in the process chamber is completed. The aforementioned operations are shown in FIGS. 13l and 13n. As a result, the apparatus is returned to the state of FIG. 13a, and a series of processes are repeatedly performed on the substrate.

After the to-be-processed substrate 440a is mounted on the substrate support plate 436, the process starts to be performed. During the process, in the process chamber, all of the inner lift pins 450 and the lift pins 460a and 460b are fallen down below the substrate support plate 436 in order to be protected by a cover (not shown) against a plasma, etc.

[Fifth Embodiment]

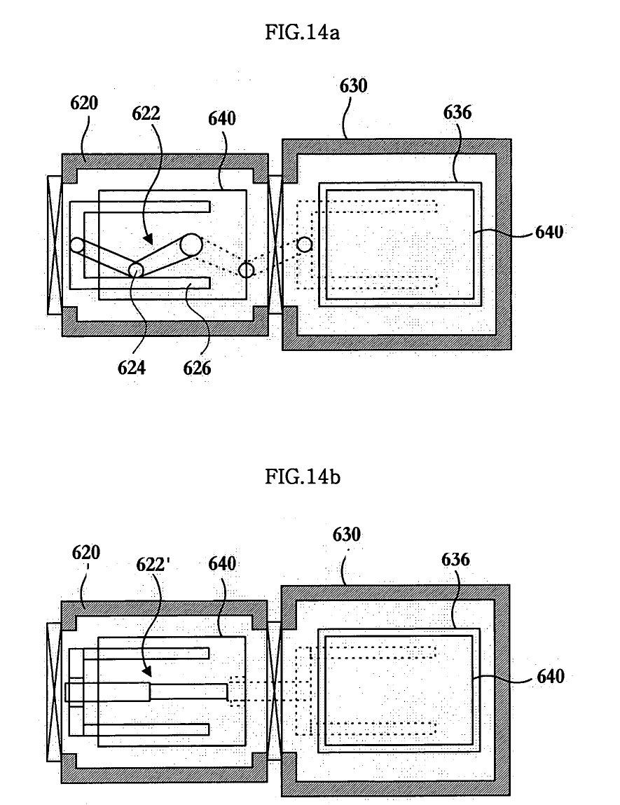

FIG. 14a is a cross-sectional view for explaining a series of operations of a robot having a robot arm to which a joint member is provided in an FPD fabricating apparatus according to a fifth embodiment of the present invention. FIG. 14b is a cross-sectional view for explaining a series of operations of a robot which is moving in a sliding manner in an FPD fabricating apparatus according to the fifth embodiment of the present invention;

Referring to FIG. 14a, the FPD fabricating apparatus according to the embodiment comprises a transfer chamber 620 used for transferring a substrate and a process chamber 630 in which a process is performed. The transfer chamber 620 is connected to the process chamber 630. The transfer chamber 620 is used as a passage through which a to-be-processed substrate is entered into the process chamber 630 from an exterior and through which a process-completed substrate is ejected from the process chamber 630 to the exterior. In other words, the transfer chamber has functions of both of a load-lock chamber and a transfer chamber of a conventional FPD fabricating apparatus.

Firstly, a robot 622 is provided to the transfer chamber 620. The substrate 640 is transferred by the robot 622 having a hand on which the substrate 640 is mounted.

In order to reduce the processing time of the FPD fabricating process, it is necessary to perform venting and pumping of the transfer chamber 620 and exchange of the substrates within a short time. If the volume of the transfer chamber 620 is large, it takes a long time to vent and pump the transfer chamber. The volume of the transfer chamber 620 is a principal factor in determining the transfer time. Therefore, the reduction of the volume of the transfer chamber results in the reduction of the transfer time. However, in a conventional case where the arm of the robot 620 is rotated, the volume of the transfer chamber 620 must be large so as to ensure the rotational radius of the robot arm. As a result, the volume of the transfer chamber 620 must be increased. Accordingly, as shown in FIG. 14a, a joint member 624 is preferably provided to the robot arm, so that the robot can have a reciprocating translational motion between the transfer chamber 620 and the process chamber 630 without having a rotational motion. As a result, the rotational radius of the robot arm can be reduced, and thus the volume of the transfer chamber 620 can be reduced.

More preferably, instead of using the robot arm having a joint member, the robot 622′ may have a reciprocating translational motion in a sliding manner, as shown in FIG. 14b. As a result, the volume of the transfer chamber 620 can be effectively reduced.

On the other hand, if the robot 622 has too much fingers, the robot 622 is so heavy that the robot 622 itself may be dropping or the fingers 626 themselves may be distorted. Therefore, it is desirable that the robot 622 has only two fingers 626 in order to minimize the weight of the robot 622. In general, it is good for the robot 622 to have many fingers for the purpose of preventing the drooping of the substrate 640 which is transferred by the robot. But, in the embodiment, since the drooping of the substrate 640 can be minimized by using fold-type outer lift bars 634, it is preferable that the robot has only two fingers which are the minimal ones for balancing the substrate.

On the other hand, there is a case that the substrate is supported by only the robot fingers without the aid of the inner lift pins 632 or the outer lift bars 634. In this case, if the robot fingers 626 support only the central portion of the substrate 640, the circumferential portions of the substrate 640 may be drooping. Otherwise, if the robot fingers 626 support only the circumferential portions of the substrate 640, the central portion of the substrate 640 may be drooping.

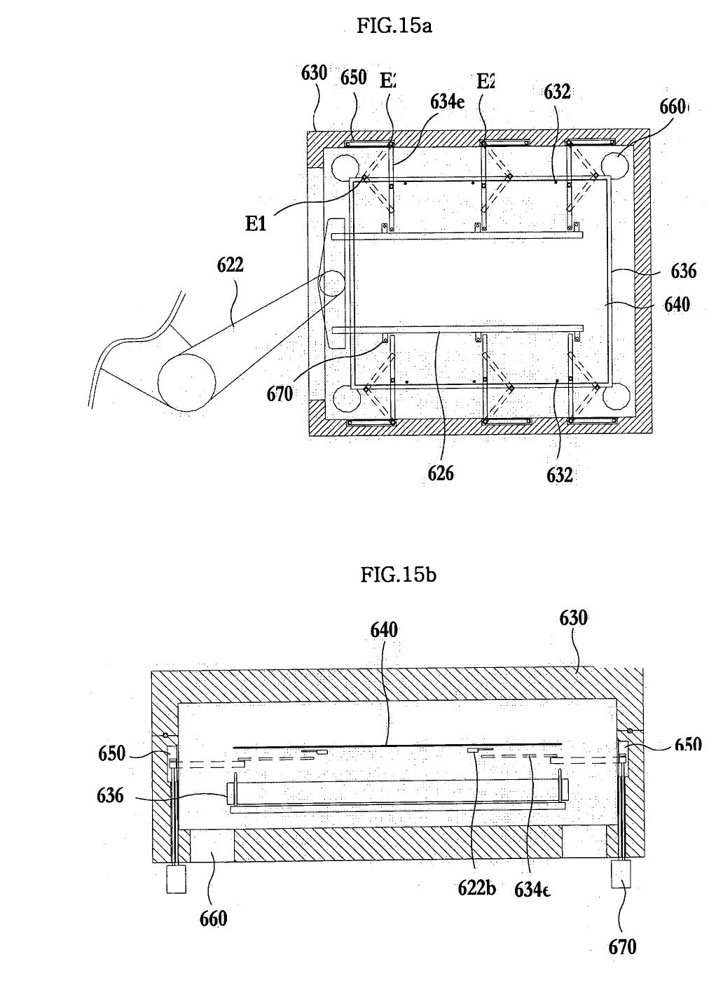

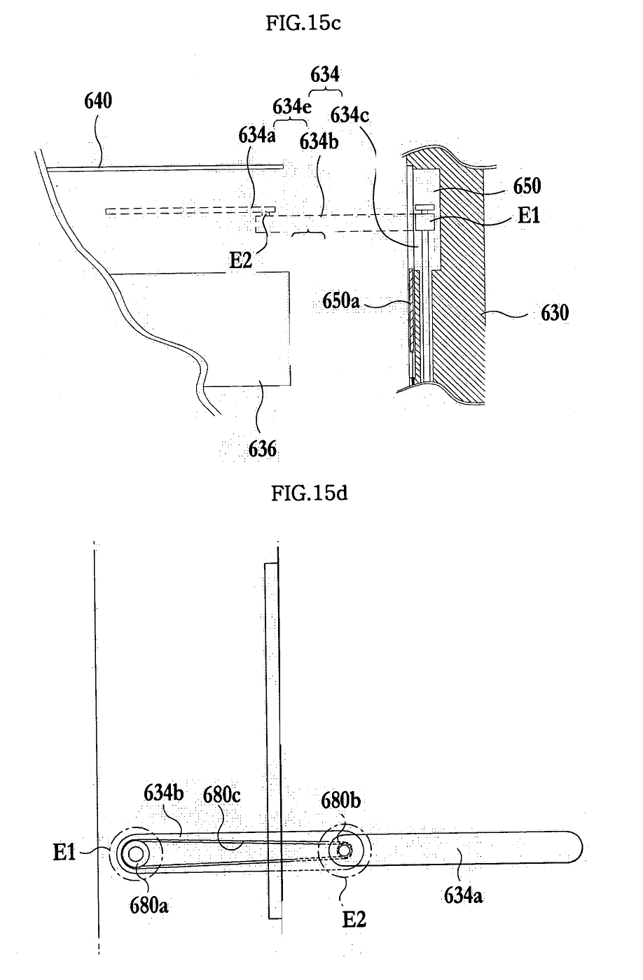

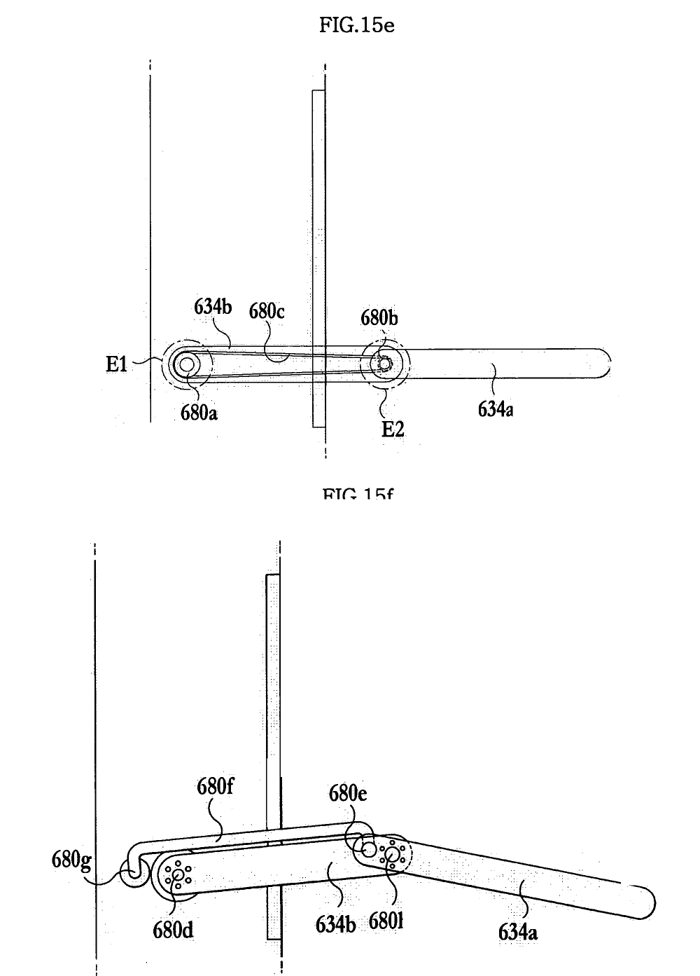

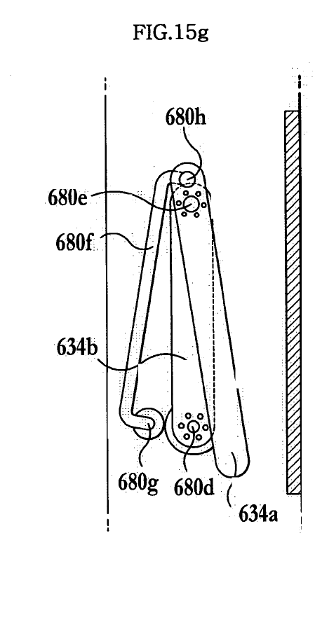

Accordingly, as shown in FIG. 15a, it is preferable that the robot fingers have substrate support wings which are branched toward the circumferential portions of the substrate for the purpose of preventing the drooping of the substrate. In addition, as shown in FIG. 15a, it is preferable that, the substrate support wings are disposed to support circumferential portions of the substrate rather than the locations of the substrate which are supported by the distal ends of horizontal support members of the outer lift bars when the horizontal support members are entirely unfolded. Needless to say, the substrate support wings must be disposed not to interfere with the folding and unfolding of the horizontal support members 634e. The reference numeral 660 indicates pumping ports for venting gas in the process chamber 630.

Next, in the process chamber 630, a substrate support plate 363, on which the substrate 640 is mounted, inner lift pins 632 for raising up and falling down the substrate, and fold-type outer lift bars 634 are provided.

A plurality of inner lift pins 632 are provided below the substrate 640 out of the substrate support plate. The substrate can be raised up and fallen down by the up-and-down motion of the inner lift pins.

Referring to FIGS. 15a and 15c, each of the fold-type outer lift bars which are incorporated into the embodiment comprises a vertical shaft 634c and a horizontal support member 634e.

The vertical shafts 634c may be disposed at outside locations out of the substrate support plate where the substrate is to be mounted or in inner-wall spaces 650 of the process chamber 630. In the embodiment, the vertical shafts 634c are disposed in inner-wall spaces 650 of the process chamber 630. In addition, the vertical shafts 634c are driven to move up and down by means of a drive motor 690.

Each of the horizontal support members 634e are constructed with a inner support bar 634a and outer support bars 634b. Each of the outer support bar 634b is at right angles to the vertical shaft 634c at the upper end thereof. The vertical shafts 634 and the outer support bar 634b are connected with a first joint E1 which are provided at the connection portion between the vertical shaft 634c and the outer support bar 634b. In other words, each of the outer support bars 634b can be rotated on the corresponding vertical shaft 634c by means of the joint E1.

Each of the inner support bars 634a is provided in parallel to the corresponding outer support bar 634b at the end portion of the outer support bar bars when the horizontal support member is entirely unfolded. A joint E2 is provided at the connection portion of the inner support bar 634a and the outer support bar 634b. In other words, the inner support bar 634a and the outer support bar 634b are connected with the second joint E2. The inner support bar 634a and the outer support bar 634b are rotated on the second joint E2. Needless to say, besides the first and second joints E1 and E2, several joints may be added to the horizontal support member 634e. But, there is no need to make the apparatus completed by providing too many joints.

Lock gates 650a are provided at the inner wall of the process chamber 630 to protect the horizontal support member 634e from a processing gas, a plasma, or the like when the horizontal support member 634e is folded and entered into the inner-wall space of the process chamber 630. Preferably, the lock gates 650a may be opened and closed with its moving up and down As described above, the fold-type horizontal support member 634e of the outer lift bars can be stretched to support the central portion of the substrate 640 without any interruption of the inner lift pins 632 in comparison to the conventional ones which are simply rotated. Accordingly, even large-area substrate 640 can be supported and transferred without its drooping at the central portion thereof.

FIGS. 15d to 15g are views for explaining a construction and a series of operations of joint structures of the fold-type outer lift bars 634 according to the fifth embodiment. In the embodiment, two types of joint structures, that is, a belt type structure and a joint type structure of the outer lift bars 634 are disclosed.

Firstly, the construction and operations of the belt type structure of the fold-type outer lift bar 634 will be described.

As shown in FIGS. 15d and 15e, a fixed belt pulley 680a is provided at the first joint E1, and a moving belt pulley 680b is proved at the second joint E2. The fixed belt pulley 680a and the moving belt pulley 680b are connected with a steel belt 680c. The fixed belt pulley 680a is fixed at the upper end of the vertical shaft 634c, so that it can be rotated together with the rotation of the vertical shaft 634c. In addition, the moving belt pulley 680b is rotated by transmission of the rotational energy of the fixed belt pulley 680a. In other words, the moving belt pulley 680b is rotated with the fixed belt pulley 680a, so that the inner support bar 634a can be rotated. Accordingly, when the fixed belt pulley 680a is rotated, the outer support bar 634b connected thereto is simultaneously rotated. In addition, the moving belt pulley 680b which is connected to the fixed belt pulley 680a with the steel belt 680c is rotated, so that the inner support bar 634a can be also rotated. As a result, when the outer support bar 634b is rotated into the process chamber, the inner support bar 634a is also rotated, so that the horizontal support member 634e can be unfold, as shown in FIG. 15d. At this time, that the rotational ratio between the fixed belt pulley 680a and the moving belt pulley 680b is preferably set to be 2:1, so that the inner support can be rotated at 180 degrees while the outer support bar 634b is rotated at 90 degrees.

Next, the construction and operations of the joint type structure of the fold-type outer lift bar 634 will be described.

In the outer lift bar having the joint type structure also comprises a vertical shaft 634c and a horizontal support member 634e. However, unlike the belt type structure, an auxiliary support bar 680f are provided to the horizontal support member 634e besides the outer support bar 634b and the inner support bar 634a. As shown in FIGS. 15f and 15g, the outer support bar 634b and the vertical shaft 634c are connected with a third joint E3, so that the outer support bar 634b can be rotated by the third joint E2. In other words, the outer support bar 634b can be rotated together with the rotation of the vertical shaft 634c. In addition, the inner support bar 634a is fixed at the other end of the outer support bar 634b with a fourth joint E4, so that the inner support bar can be rotated. In addition, an auxiliary joint E5 is provided at a predetermined location near the vertical shaft on the inner wall of the process chamber. In addition, an auxiliary support bar 690f is provided. The one end of the auxiliary support bar is fixed and rotated at the first auxiliary joint E5. The other end of the auxiliary support bar is fixed and rotated at an second auxiliary join E6 which is disposed at an extending portion of the end of the inner support bar 634a, wherein the end of the inner support bar is connected to the fourth joint E4. As shown in FIGS. 15f and 15g, it is preferable that each of the ends of the auxiliary support bar is perpendicularly angled and has a predetermined length. As shown in FIG. 15g, when the outer support bar is folded and entered into the inner-wall space of the process chamber 630, the extending portion of the inner support bar 634a which is fixed at the second auxiliary joint E6 is located opposite to the fourth joint E4, so that the inner support bar can be folded and entered into the inner-wall space.

After that, as shown in FIG. 15f, when the outer support bar 634b is rotated to be perpendicular to the inner wall by the rotation of the vertical shaft 634c, the extending portion of the inner support bar 634a is located toward the outer support bar 634b, so that the inner support bar can be unfold and apart from the outer support bar 634b.

As described, in the fold-type outer lift bar having the joint structure, the inner support bar 634a can be deeply stretched to support the central portion of the substrate without any interruption of the inner lift pins 632.

As described above, according to the present invention, it is advantageous that a load-lock chamber for transferring a substrate and a transfer chamber is incorporated into a single transfer chamber 120, so that space of the apparatus can be remarkably reduced and cost of the apparatus can be reduced.

In addition, according to the present invention, it is advantageous that the substrate may be raised up and fallen down by using the carrier plates 150a and 150b, so that even large-area substrate can be stably transferred at high speed without bending, disrupting or vibration of the substrate

In addition, according to the present invention, it is advantageous that the substrates may be transferred by the double blade member 270 capable of raising up two substrates simultaneously, so that the transfer time can be effectively reduced and thus yield of production can be improved.

In addition, according to the present invention, it is advantageous that the substrate may be raised up and fallen down by using only the inner lift pins 150, so that the bending of the substrate can be prevented at the aid of the upper lift bars 160a and the lower lift bars 160b.

In addition, according to the present invention, it is advantageous that the substrate may be transferred by using the two-stage slider member having only the forward-and-backward motion instead of the conventional robot having an up-and-down motion, a rotational motion, and forward-and-background motion, so that the substrate can be effectively transferred in even a small space. Therefore, it is advantageous that the overall space of the apparatus can be remarkably reduced and cost of the apparatus can be reduced.

In addition, according to the present invention, it is advantageous that the fold-type outer lift bars 134 may be used, so that the inner support bar can be deeply stretched to support the central portion of the substrate 140 without any interruption of the inner lift pins 132 even in the case that the interval of the inner lift pins is too narrow. Therefore, it is advantageous that the bending of the substrate can be prevented. In addition, it is advantageous that the substrate can be transferred while the drooping of the substrate can be minimized at the aid of the substrate support wings 170.

Although the foregoing description has been made with reference to the preferred embodiments, it is to be understood that changes and modifications of the present invention may be made by the ordinary skilled in the art without departing from the spirit and scope of the present invention and appended claims.

What is claimed is:

1. An FPD fabricating apparatus comprising:
a process chamber in which a process is performed;
a substrate support plate provided in the process chamber, wherein a to-be-processed substrate is mounted on the substrate support plate;
a transfer chamber through which the substrate is entered into the process chamber from an exterior or through which the substrate is ejected from the process chamber to the exterior;
a first carrier plate and a second carrier plate on which the substrate is mounted, wherein each of the first and second carrier plate has a forked shape of which ends are directed from the transfer chamber to the process chamber;
a robot provided in the transfer chamber, wherein the robot comprises an arm of which end is directed from the transfer chamber to the process chamber, and wherein the arm has a reciprocating motion between the transfer chamber and the process chamber, thereby the robot transferring the first and second carrier plates;
carrier plate lift pins provided in the transfer chamber and the process chamber, wherein the carrier plate lift pins are raised up and fallen down while avoiding contact with forked prongs of the robot arm, so that the first and second carrier plates mounted on the robot arm can be raised up and fallen down; and
substrate lift pins provided in the transfer chamber and the process chamber, wherein the substrate lift pins are raised up and fallen down while avoiding forked prongs of the robot arm, the first carrier plate, and the second carrier plate, so that the substrates mounted on the carrier plates can be raised up and fallen down.

2. The FPD fabricating apparatus according to claim 1, wherein the robot arm has a reciprocating translational motion without having a rotational motion.

3. The FPD fabricating apparatus according to claim 1, wherein the substrate lift pins are disposed in order to uniformly support the entire substrate.

4. An FPD fabricating apparatus comprising:
a process chamber in which a process is performed;
a substrate support plate provided in the process chamber, wherein a to-be-processed substrate is mounted on the substrate support plate;
a transfer chamber through which the substrate is entered into the process chamber from an exterior or through which the substrate is ejected from the process chamber to the exterior;
a robot provided in the transfer chamber, wherein the robot comprises a double blade member having an upper blade and a lower blade on which the substrate is mounted, wherein the double blade member has a reciprocating motion between the process chamber and the transfer chamber, and wherein each of the upper and lower blades has a forked shape of which end is directed from the transfer chamber to the process chamber;
inner lift pins provided in the transfer chamber and the process chamber, wherein the outer lift pins are disposed below the substrate which is mounted on the double blade member, and wherein the inner lift pins are raised up and fallen down while avoiding contact with the forked prongs of the double blade; and
outer lift pins provided in the transfer chamber and the process chamber, wherein the outer lift pins are disposed at outside locations just below the substrate which is mounted on the double blade member, wherein the end portions of the outer lift pins are angled at a horizontal direction, and wherein the outer lift pins are rotated on their own vertical shafts.

5. The FPD fabricating apparatus according to claim 4, wherein the double blade member has a reciprocating translational motion without having a rotational motion.

6. The FPD fabricating apparatus according to claim 4, wherein the inner lift pins are disposed in order to uniformly support the entire substrate.

7. An FPD fabricating apparatus comprising:
a process chamber in which a process is performed;
a substrate support plate provided in the process chamber, wherein a to-be-processed substrate is mounted on the substrate support plate;
a transfer chamber through which the substrate is entered into the process chamber from an exterior or through which the substrate is ejected from the process chamber to the exterior;
a robot provided in the transfer chamber, wherein the robot comprises an arm, wherein the substrate is supported by the arm, and wherein the arm has a reciprocating motion between the process chamber and the transfer chamber;
lower lift bars provided in the process chamber, wherein the lower lift pins are disposed at outside locations just below the substrate which is mounted on the arm, and wherein the end portions of the lower lift bars are angled at a horizontal direction;
upper lift bars provided in the process chamber, wherein the upper lift pins are disposed at outside locations just below the substrate which is mounted on the arm, wherein the end portions of the upper lift bars are angled at a horizontal direction, and wherein the upper lift bars are arranged to be raised up to higher locations than the lower lift bars are;
inner lift pins provided in the process chamber, wherein the inner lift pins are disposed below the substrate which is mounted on the arm, the inner lift pins are raised up and fallen down while avoiding contact with the arm; and
stand-by lift bars provided in the transfer chamber, wherein the stand-by lift pins are disposed at outside locations just below the substrate which is mounted on the arm, and wherein the end portions of the stand-by lift bars are angled at a horizontal direction.

8. The FPD fabricating apparatus according to claim 7, wherein the arm has a reciprocating translational motion forwards and backward.

9. The FPD fabricating apparatus according to claim 7, wherein the arm is extended in a direction from the transfer chamber to the process chamber to support a central portion of the substrate.

10. The FPD fabricating apparatus according to claim 7, wherein the angled end portions of the upper lift bars, the lower lift bars, and the stand-by lift bars are stretched near to the central portion of the substrate.

11. An FPD fabricating apparatus comprising:
a process chamber in which a process is performed;
a transfer chamber being a passage through which the substrate is entered into the process chamber from an exterior or through which the substrate is ejected from the process chamber to the exterior;
a transfer slider member provided in the transfer chamber, wherein a transfer slider member has a reciprocating translational motion between the process chamber and the transfer chamber to transfer a substrate; and
a plurality of lift pins provided in the process chamber and the transfer chamber, wherein the substrate is raise up and fallen down by the plurality of lift pins.

12. The FPD fabricating apparatus according to claim 11, wherein the transfer slider member is a two-stage slider member comprising a pair of a lower slider and an upper slider.

13. The FPD fabricating apparatus according to claim 12, wherein each of the upper slider and the lower slider comprises:
a reference panel
liner guides provided on the reference panel;
a carrier having a reciprocating translational motion along the liner guides;
a ball screw provided in parallel to the liner guides for allowing the carrier to have the reciprocating translational motion; and
a drive motor for driving a rotation of the ball screw,
wherein the reference panel of the upper slider is mounted on the carrier of the lower slider; and
wherein the blade for supporting the substrate is mounted on the carrier of the upper slider.

14. The FPD fabricating apparatus according to claim 12, wherein each of the upper slider and the lower slider comprises:
a reference panel
liner guides provided on the reference panel;
a carrier having a reciprocating translational motion along the liner guides;
a iron-core coil provided below the carrier; and
a permanent magnet provided opposite to iron-core coil and in parallel to the liner guides,
wherein the reference panel of the upper slider is mounted on the carrier of the lower slider, and
wherein the blade for supporting the substrate is mounted on the carrier of the upper slider.

15. An FPD fabricating apparatus comprising:
a process chamber in which a process is performed;
a substrate support plate provided in the process chamber, wherein a substrate is mounted on the substrate support plate;
a transfer chamber connected to the process chamber, wherein the transfer chamber is used as a passage through which the substrate is entered into the process chamber from an exterior and the substrate is ejected from the process chamber to the exterior;
a robot provided in the transfer chamber, wherein the substrate is transferred by the robot, and wherein the robot has a reciprocating motion between the process chamber and the transfer chamber;
a plurality of inner lift pins provided at locations out of the substrate support plate where the substrate is to be mounted, wherein the substrate is raised up and fallen down by the up-and-down motion of the inner lift pins; and
fold-type outer lift bars provided at outside locations out of the substrate support plate where the substrate is to be mounted, wherein each of the fold-type outer lift bars comprises a vertical shaft and a horizontal support member, wherein the vertical shaft is arranged to have a up-and-down motion, wherein the horizontal support member comprises an outer support bar perpendicularly connected to the vertical shaft with a first joint which is provided at an upper end of the vertical shaft and an inner support bar connected to the outer support bar with a second joint which is provided at an end of the outer support bar, and wherein the horizontal support member is folded on the center of the second joint.

16. The FPD fabricating apparatus according to claim 15, wherein the fold-type outer lift bar is arranged to support a location which is closer to the central portion of the substrate than a location of the substrate which the inner lift pin supports when the inner lift pin is entirely unfold without interference.

17. The FPD fabricating apparatus according to claim 15, wherein the first and second joint are connected with a power transmission means, wherein the first joint is rotated by the rotation of the vertical shaft, and wherein the rotational energy of the first joint is transmitted to the second joint the power transmission means, thereby the rotations of the second joint is interlocked with that of the first joint.

18. The FPD fabricating apparatus according to claim 17, wherein the power transmission means is a belt.

19. The FPD fabricating apparatus according to claim 18, wherein the power transmission means is a steel belt.

20. The FPD fabricating apparatus according to claim 15, wherein the outer lift bar further comprises an auxiliary support bar, wherein the one end of the auxiliary support bar is rotated independently from the vertical shaft by a first auxiliary joint which is provided near the vertical shaft on the inner wall of the process chamber, and wherein the other end of the auxiliary support bar is connected with the second auxiliary joint at an extending portion of the end of the inner support bar which is connected to the second joint.

21. The FPD fabricating apparatus according to claim 20, wherein each of the ends of the auxiliary support bar is perpendicularly angled and has a predetermined length.

22. The FPD fabricating apparatus according to claim 15, wherein the vertical shaft of the outer support bar is provided with the inner-wall space of the process chamber.

23. The FPD fabricating apparatus according to claim 22, wherein lock gates are provided at the inner wall of the process chamber to protect the horizontal support member from a processing gas when the horizontal support member is folded and entered into an inner-wall space of the process chamber.

24. The FPD fabricating apparatus according to claim 15, wherein the robot is arranged to have a forward-and-backward motion in a sliding manner.

25. The FPD fabricating apparatus according to claim 15, wherein the robot comprises a joint at a predetermined portion thereof, where the robot has a reciprocating motion between the process chamber and the transfer chamber without having a rotational motion.

26. The FPD fabricating apparatus according to claim 15, wherein the robot comprises two fingers.

27. The FPD fabricating apparatus according to claim 26, wherein each of the fingers has a plurality of substrate support wings which are branched at predetermined location of the finger, and wherein the length of the substrate support wings is set to be longest within a range where the substrate support wing can not interfere with the rotational motion of the outer lift bar.
